(19) United States
(12) Patent Application Publication
(10) Pub. No.: US 2012/0058639 A1
(43) Pub. Date: Mar. 8, 2012

(54) SEMICONDUCTOR DEVICES AND METHODS OF FABRICATING THE SAME

(76) Inventors: Jae-Hwang SIM, Hwaseong-si (KR); Jong-Min LEE, Jung-gu (KR); Hojun SEONG, Suwon-si (KR)

(21) Appl. No.: 13/194,229

(22) Filed: Jul. 29, 2011

(30) Foreign Application Priority Data
Sep. 7, 2010 (KR) 10-2010-0087619

(51) Int. Cl. H01L 21/283

(52) U.S. Cl. 438/666; 257/E21.159

(57) ABSTRACT

A method of forming a nonvolatile memory device includes providing conductive pillars disposed in a first insulating layer and disposed on a semiconductor substrate, providing an etch stop layer on the first insulating layer, disposing a mold layer on the etch stop layer, and forming grooves in the mold layer. The grooves respectively extend over the conductive pillars in a first direction. The method further includes patterning the etch stop layer using the grooves to form holes respectively corresponding to the conductive pillars, and filling a metal into the grooves and the holes. The metal in the holes contacts the conductive pillars.

### CROSS-REFERENCE TO RELATED APPLICATION

This application claims priority to Korean Patent Application No. 2010-0087619, filed on Sep. 7, 2010, the disclosure of which is incorporated herein in its entirety by reference.

### BACKGROUND

1. Technical Field

The present disclosure relates to a semiconductor device and a method of fabricating the same, and more particularly, to semiconductor devices including an interconnection structure, and methods of fabricating the same.

2. Related Art

Semiconductor devices may be classified into, e.g., memory devices storing logic data, logic devices performing a logic operation on logic data, and hybrid semiconductor devices. The hybrid semiconductor devices may include, e.g., a memory element and a logic element. With the trend towards high speed operation and lower power consumption of electronic devices, semiconductor devices embedded into these electronic devices may require fast operation speed and/or low operation voltage.

### SUMMARY

According to an exemplary embodiment, a method of forming a nonvolatile memory device comprises providing conductive pillars disposed in a first insulating layer and disposed on a semiconductor substrate, providing an etch stop layer on the first insulating layer, disposing a mold layer on the etch stop layer, forming grooves in the mold layer, the grooves respectively extending over the conductive pillars in a first direction, patterning the etch stop layer using the grooves to form holes respectively corresponding to the conductive pillars, and filling a metal into the grooves and the holes, the metal in the holes contacting the conductive pillars.

According to an exemplary embodiment, a method of forming a nonvolatile memory device comprises providing conductive pillars disposed in a first insulating layer and disposed on a semiconductor substrate, providing an etch stop layer having holes on the first insulating layer, disposing a mold layer on the etch stop layer, forming grooves in the mold layer, the grooves respectively extending over the conductive pillars in a first direction, patterning the mold layer in the holes using the grooves to form openings therein respectively corresponding to the conductive pillars, and filling a metal into the grooves and the openings, the metal in the openings contacting the conductive pillars.

According to an exemplary embodiment, a nonvolatile memory device comprises a bit line extending in a first direction, a conductive pillar disposed under the bit line, and a metal contact extending from the bit line to contact the conductive pillar, wherein the bit line and the metal contact comprise a first pair of self-aligned sidewalls disposed in the first direction and a second pair of self-aligned sidewalls disposed in a second direction perpendicular to the first direction.

According to an exemplary embodiment, a nonvolatile memory device comprises conductive pillars disposed in a first insulating layer on a semiconductor substrate, bit lines disposed in a second insulating layer on the first insulating layer, the bit lines extending in a first direction over the conductive pillars; and metal contacts protruding from the bit lines and respectively contacting the conductive pillars, and an air gap formed in the second insulating layer, the air gap extending in the first direction disposed between two immediately adjacent bit lines arranged in a second direction that is perpendicular to the first direction, wherein a width of respective bit lines in the second direction is substantially the same as a width of respective metal contacts in the second direction.

According to an exemplary embodiment, a memory device comprises a semiconductor substrate, a first insulating layer disposed on the semiconductor substrate, a first conductive pillar and a second conductive pillar disposed in the first insulating layer, a second insulating layer disposed on the first insulating layer, a first bit line and a second bit line disposed immediately next to each other in the second insulating layer, the first and second bit lines extending in a first direction and spaced apart from each other in a second direction substantially perpendicular to the first direction, a first metal contact extending from the first bit line toward the semiconductor substrate, and a second metal contact extending from the second bit line toward the semiconductor substrate, a contact mold layer having a plurality of openings, the contact mold layer disposed on the first insulating layer, an etch stop pattern disposed on the contact mold layer, and an air gap formed in the second insulating layer, the air gap disposed between the first and second bit lines and on the contact mold layer, wherein the first and second metal contacts are respectively disposed through first and second openings of the contact mold layer to electrically connect the first conductive pillar and the first bit line and the second conductive pillar and the second bit line.

### BRIEF DESCRIPTION OF THE DRAWINGS

The accompanying drawings are included to provide a further understanding of the exemplary embodiments, and are incorporated in and constitute a part of this specification. The drawings illustrate exemplary embodiments and, together with the description, serve to explain principles thereof. In the drawings:

FIG. 1A is a plan view of a semiconductor device, according to an exemplary embodiment;

FIG. 1B is a cross-sectional view taken along lines I-I′ and II-II′ of FIG. 1A;

FIG. 1C is a perspective view illustrating an interconnection and a contact part of FIG. 1A;

FIG. 1D is a perspective view illustrating an air gap of FIG. 1A;

FIG. 2A is a cross-sectional view taken along line I-I′ of FIG. 1A, according to an exemplary embodiment;

FIG. 2B is a cross-sectional view taken along line I-I′ of FIG. 1A, according to an exemplary embodiment;

FIG. 2C is a cross-sectional view taken along line I-I′ of FIG. 1A, according to an exemplary embodiment;

FIG. 2D is a cross-sectional view taken along line I-I′ of FIG. 1A, according to an exemplary embodiment;

FIG. 2E is a cross-sectional view taken along line I-I′ of FIG. 1A, according to an exemplary embodiment;

FIG. 2F is a cross-sectional view taken along lines I-I′ and II-II′ of FIG. 1A, according to an exemplary embodiment;

FIGS. 3A, 4A, 5A, 6A, 7A, 8A, 9A, and 10A are plan views for describing stages in a method of fabricating a semiconductor device, according to an exemplary embodiment;

FIGS. 3B, 4B, 5B, 6B, 7B, 8B, 9B, and 10B are cross-sectional views taken along lines I-I′ and II-II′ of FIGS. 3A to 10A, respectively;

FIG. 11 is a schematic sectional view for describing a method of fabricating a semiconductor device, according to an exemplary embodiment;

FIG. 12 is a schematic sectional view for describing a method of fabricating a semiconductor device, according to an exemplary embodiment;

FIGS. 13A, 14A, 15A, and 16A are plan views for describing stages in a method of fabricating a semiconductor device, according to an exemplary embodiment;

FIGS. 13B, 14B, 15B, and 16B are cross-sectional views taken along lines I-I′ and II-II′ of FIGS. 13A to 16A;

FIG. 17A is a plan view illustrating a semiconductor device, according to an exemplary embodiment;

FIG. 17B is a cross-sectional view taken along lines III-III′ and IV-IV′ of FIG. 17A;

FIGS. 18A, 19A, 20A, 21A, and 22A are plan views for describing stages in a method of fabricating a semiconductor device, according to an exemplary embodiment;

FIGS. 18B, 19B, 20B, 21B, and 22B are cross-sectional views taken along lines III-III′ and IV-IV′ of FIGS. 18A to 22A, respectively;

FIG. 23A is a plan view illustrating a semiconductor device, according to an exemplary embodiment;

FIG. 23B is a cross-sectional view taken along lines V-V′ and VI-VI′ of FIG. 23A;

FIG. 24A is a plan view illustrating a semiconductor device according to an exemplary embodiment;

FIG. 24B is a cross-sectional view taken along lines VII-VII′ and VIII-VIII′ of FIG. 24A;

FIG. 25 is a block diagram illustrating an electronic system including a semiconductor device, according to an exemplary embodiment; and

FIG. 26 is a block diagram illustrating a memory card including a semiconductor device, according to an exemplary embodiment.

### DETAILED DESCRIPTION OF EMBODIMENTS

Exemplary embodiments of the inventive concept will now be described more fully with reference to the accompanying drawings. The inventive concept may, however, embodied in many different forms and should not be construed as limited to only the exemplary embodiments set forth herein.

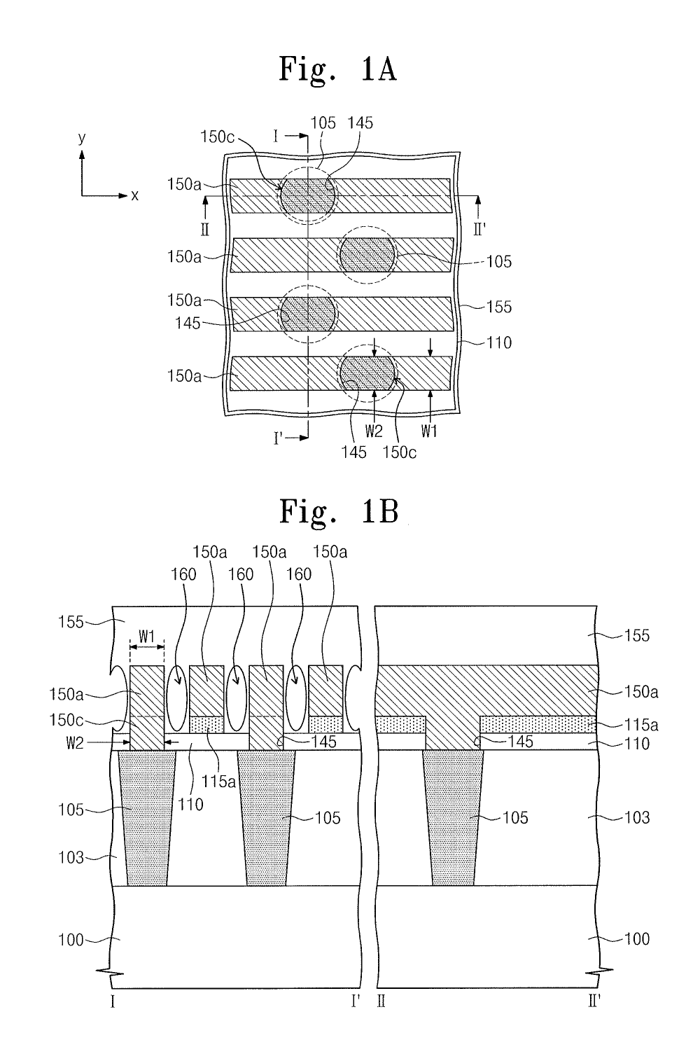

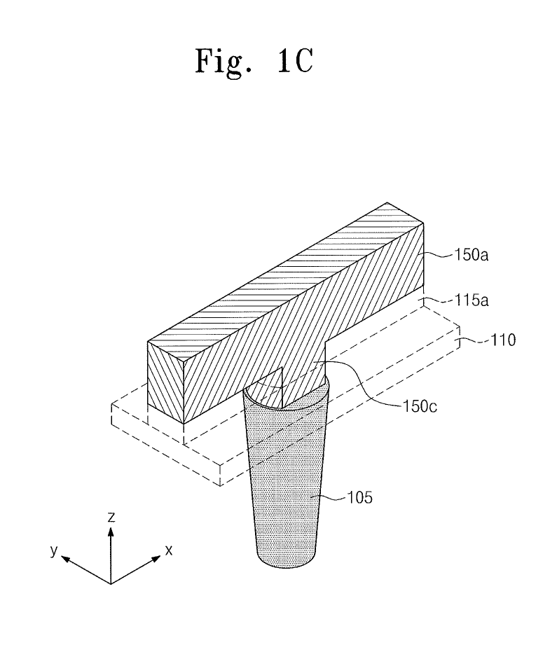

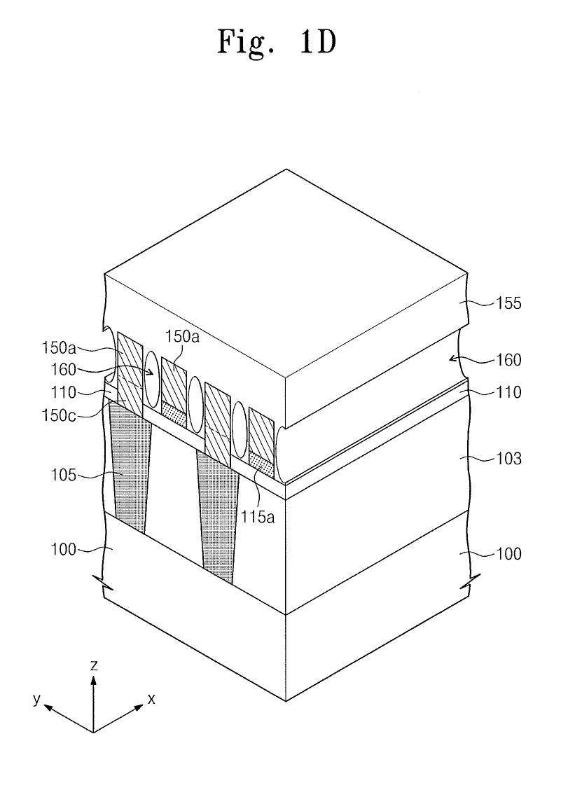

FIG. 1A is a plan view of a semiconductor device according to an exemplary embodiment, and FIG. 1B is a cross-sectional view taken along lines I-I′ and II-II′ of FIG. 1A. FIG. 1C is a perspective view illustrating a interconnection and a contact part of FIG. 1A, and FIG. 1D is a perspective view illustrating an air gap of FIG. 1A.

Referring to FIGS. 1A and 1B, a lower interlayer dielectric 103 may be disposed on a semiconductor substrate 100 (hereinafter referred to as ‘substrate’), and a contact mold layer 110 may be disposed on the lower interlayer dielectric 103. The substrate 100 may be a silicon substrate, a germanium substrate or a silicon-germanium substrate. The lower interlayer dielectric 103 may be single-layered or multi-layered. The lower interlayer dielectric 103 may include oxide, nitride and/or oxy-nitride.

Interconnections 150a extending in parallel in a first direction may be disposed on the contact mold layer 110. The interconnections 150a may be spaced apart from one another in a second direction perpendicular to the first direction. The first and second directions may be parallel to a top surface of the substrate 100. The first direction may correspond to an x-axis direction in FIG. 1A, and the second direction may correspond to a y-axis direction in FIG. 1A.

Contact parts 150c may be connected to bottom surfaces of the interconnections 150a, respectively. Each of the contact parts 150c may extend downwardly from some portion of the bottom surface of the interconnection 150a to penetrate the contact mold layer 110. The contact part 150c and the interconnection 150a connected to each other may make one body. That is, the contact part 150c and the interconnection 150a may contact each other without a boundary. A plurality of conductive pillars 105 may be disposed in the lower interlayer dielectric 103. The conductive pillars 105 may penetrate the lower interlayer dielectric 103 and may be laterally spaced apart from one another. Each of the contact parts 150c may penetrate the contact mold layer 110 and be connected to a top surface of each of the conductive pillars 105.

According to an embodiment, as disclosed in FIG. 1A, the contact parts connected to the odd-numbered interconnections may be arranged in the second direction to constitute a first column, and the contact parts connected to the even-numbered interconnections may be arranged in the second direction to constitute a second column disposed at one side of the first column. The odd-numbered and even-numbered interconnections 150a may be arranged in parallel to one another, such that the contact parts 150c in the first and second columns may not overlap each other in the first direction. According to an embodiment, as disclosed in FIG. 1A, the contact parts 105 may be arranged in a zigzag form or offset along the second direction. The conductive pillars 105 may be disposed under the contact parts 150c, respectively. Thus, the conductive pillars 105 may be divided into a first group constituting the first column, and a second group constituting the second column. The conductive pillars 105 may be arranged in a zigzag form or offset along the second direction.

Referring to FIGS. 1A, 1B and 1C, the interconnection 150a may have a first width W1 in the second direction, and the contact part 150c may have a second width W2 in the second direction. In an embodiment, the first width W1 is substantially the same as the second width W2. According to an embodiment, the contact part 150c may include a pair of first sidewalls respectively self-aligned on both sidewalls of the interconnection 150a. That is, the first sidewall of the contact part 150c and one sidewall of the interconnection 150a may form a plane which is substantially perpendicular to the top surface of the substrate 100. The pair of first sidewalls of the contact part 150c may be extended in parallel along the first direction. The contact part 150c may further include a pair of second sidewalls extending in the second direction. According to an embodiment, as disclosed in FIGS. 1A and 1C, the second sidewalls of the contact part 150c may have a round shape in plan view. However, embodiments are not limited thereto. For example, the second sidewalls of the contact part 150c may have other shapes.

A blocking dielectric pattern 115a may be disposed between the interconnection 150a and the contact mold layer 110. In this case, an upper end of the contact part 150c may be disposed at a higher level than a top surface of the contact mold layer 110. That is, the contact part 150c may fill a contact hole 145 penetrating the contact mold layer 110 and be projected to a higher level than the top surface of the contact mold layer 110. The upper end of the contact part 150c may be positioned at the substantially same level as a top surface of the blocking dielectric pattern 115a. According to an embodiment, blocking dielectric patterns 115a separated from each other by the contact part 150c may be disposed under the interconnection 150a. The second sidewall of the contact part 150c may contact the blocking dielectric pattern 115a. According to an embodiment, the blocking dielectric pattern 115a may include both sidewalls self-aligned to both sidewalls of the interconnection 150a. The blocking dielectric pattern 115a and the contact part 150c may include sidewalls self-aligned to the sidewalls of the interconnection 150a.

The blocking dielectric pattern 115a may include a dielectric material having an etch selectivity with respect to the contact mold layer 110. For example, when the contact mold layer 110 includes oxide, the blocking dielectric pattern 115a may include nitride and/or oxynitride. However, embodiments are not limited thereto. The contact mold layer 110 may include another dielectric material, and the blocking dielectric pattern 115a may include another dielectric material having an etch selectivity with respect to the contact mold layer 110.

The conductive pillar 105 may include a conductive material. For example, the conductive pillar 105 may include at least one selected from doped semiconductor (e.g., doped silicon), metal (e.g., tungsten), conductive metal nitride (e.g., titanium nitride, or tantalum nitride), transition metal (e.g., titanium, or tantalum), or conductive metal-semiconductor compound (e.g., metal silicide).

The contact part 150c may include the same conductive material as the interconnection 150a. For example, the interconnection 150a and the contact part 150c may include metal such as, for example, tungsten, aluminum, or copper. Also, the interconnection 150a and the contact part 150c may include a barrier metal (e.g., titanium nitride, or tantalum nitride) for minimizing diffusion of metal. The interconnection 150a and the contact part 150c may further include a glue layer such as, for example, a titanium layer, or a tantalum layer.

An upper interlayer dielectric 155 may be disposed on the interconnections 150a. Air gaps 160 may be formed between the interconnections 150a. In an embodiment, each of the air gaps 160 may be disposed between a pair of the interconnections 150a adjacent to each other. A portion of the upper interlayer dielectric 115 may be disposed in a space between the pair of the interconnections 150a adjacent to each other. For example, the air gap 160 may be enclosed by the upper interlayer dielectric 155. As disclosed in FIG. 1D, the air gap 160 may extend in parallel to the interconnections 150a. According to an embodiment, as disclosed in FIGS. 1B and 1D, a lower end of the air gap 160 may be positioned at a lower level than a bottom surface of the interconnection 150a. Therefore, a part of the air gap 160 may be positioned at a side of an upper portion of the contact part 150c, which is positioned at a higher level than a top surface of the contact mold layer 110. According to an embodiment, an upper end of the air gap 160 may be positioned at the substantially same level as the top surface of the interconnection 150a. The upper interlayer dielectric 155 may be single-layered or multi-layered. According to an embodiment, the upper interlayer dielectric 155 may include oxide.

According to an embodiment, the air gaps 160 are disposed between the interconnections 150a. The air gaps 160 can minimize a parasitic capacitance between the interconnections 150a adjacent to each other. Therefore, a signal delay due to the parasitic capacitance between the interconnections 150a may be minimized, so that a semiconductor device with superior reliability may be realized. As the parasitic capacitance is minimized by the air gaps 160, the distance between the interconnections 150a can be minimized. The first width W1 of the interconnection 150a may be substantially the same as the second width W2 of the contact part 150c. Therefore, the density of the interconnections 150a and the contact parts 150c per unit area may be increased.

The foregoing semiconductor device may be implemented in the form of a hybrid device including a logic device and a semiconductor memory device, or a logic device and a memory device together.

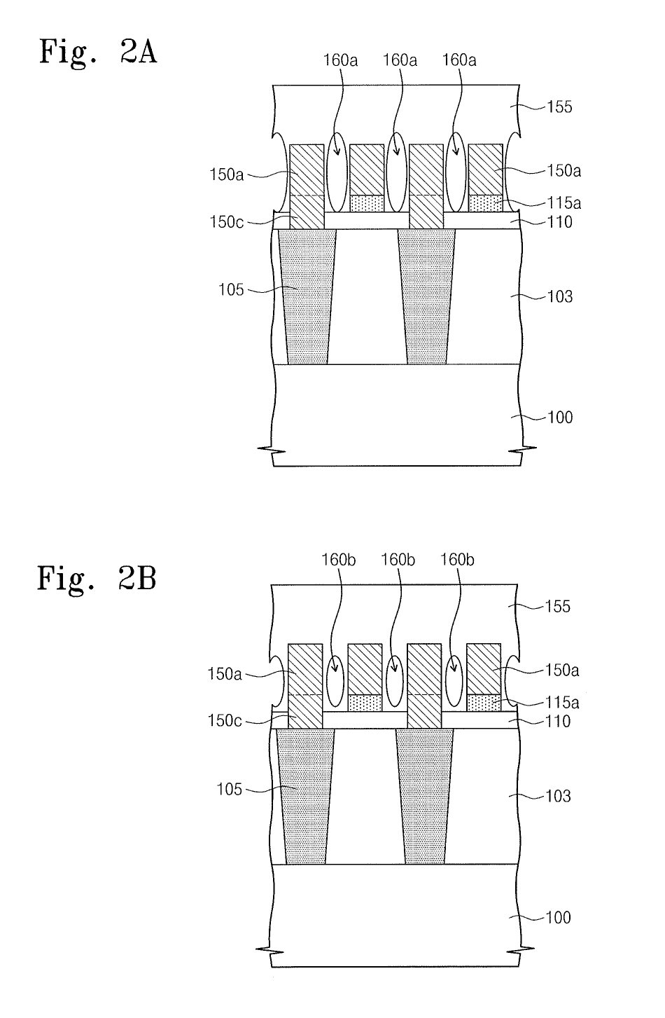

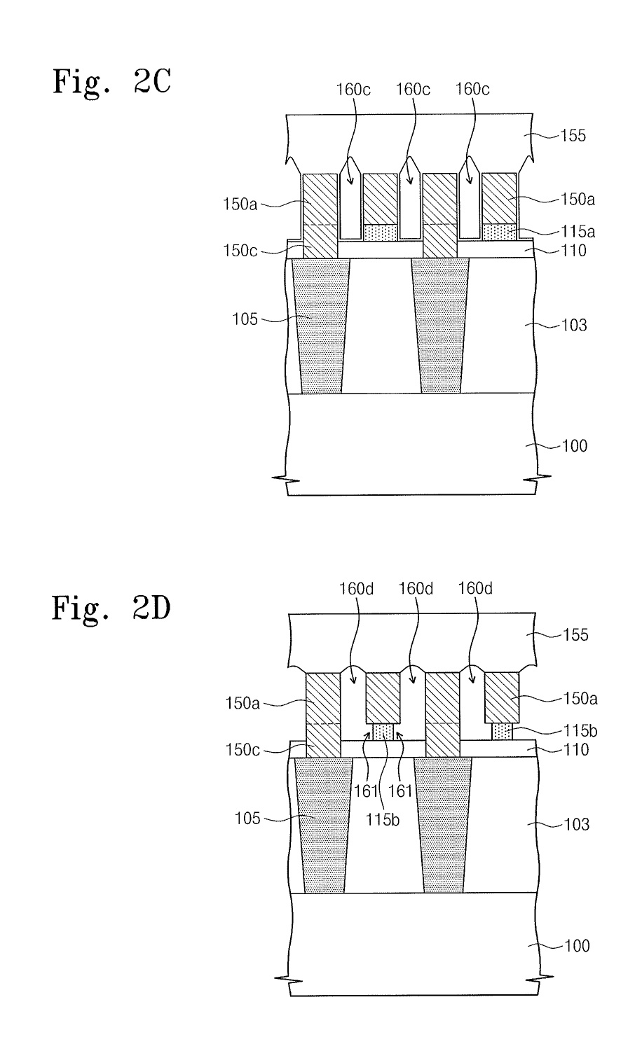

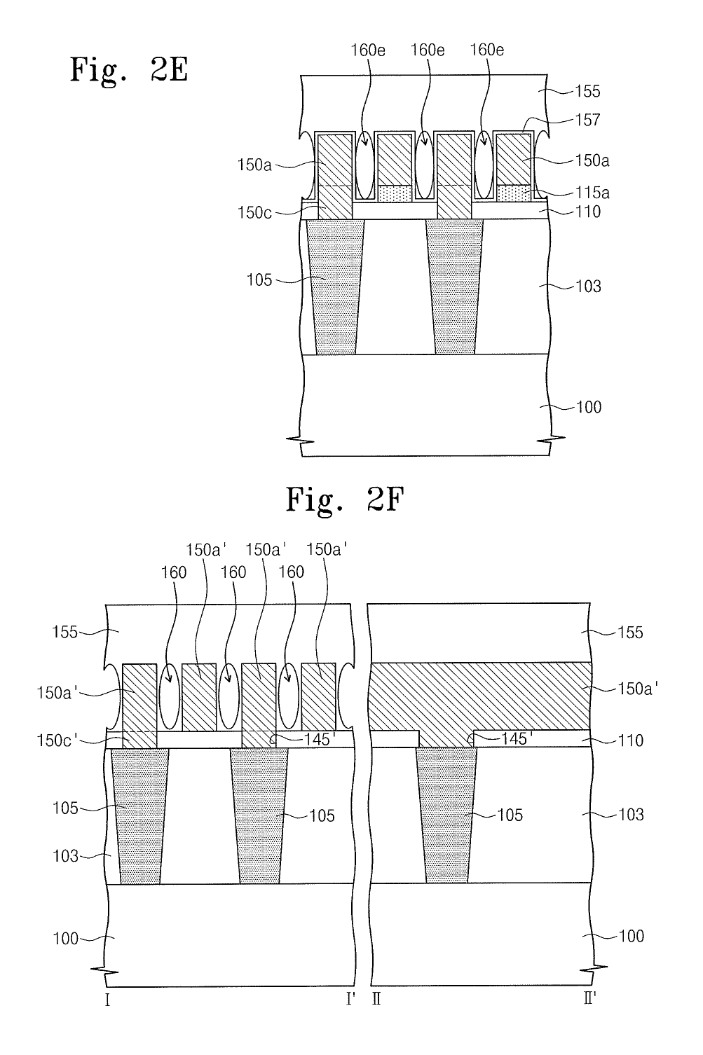

FIG. 2A is a cross-sectional view taken along line I-I′ of FIG. 1A to illustrate a semiconductor device according to an exemplary embodiment, and FIG. 2B is a cross-sectional view taken along line I-I′ of FIG. 1A to illustrate a semiconductor device according to an exemplary embodiment.

Referring to FIG. 2A, an upper end of an air gap 160a may be higher than the top surface of the interconnection 150a. A lower end of the air gap 160a may be positioned at a lower level than the bottom surface of the interconnection 150a.

According to an embodiment, as disclosed in FIG. 2B, an upper end of an air gap 160b may be positioned at a lower level than the top surface of the interconnection 150a. In this case, a lower end of the air gap 160b may be positioned at a lower level than the bottom surface of the interconnection 150a.

FIG. 2C is a cross-sectional view taken along line I-I′ of FIG. 1A to illustrate a semiconductor device according to an exemplary embodiment.

Referring to FIG. 2C, an upper portion of an air gap 160c may have a tapered shape toward a top surface of the upper interlayer dielectric 155. That is, the width of the upper portion of the air gap 160c may decrease gradually as it goes to the top surface of the upper interlayer dielectric 155. According to an embodiment, an upper end of the air gap 160c may be positioned at a higher level than the top surface of the interconnection 150a. Therefore, at least some of the tapered portion of the air gap 160c may be positioned at a higher level than the top surface of the interconnection 150a.

FIG. 2D is a cross-sectional view taken along line I-I′ of FIG. 1A to illustrate a semiconductor device according to an exemplary embodiment.

Referring to FIG. 2D, the width of a blocking dielectric pattern 115b under the interconnection 150a may be smaller than the width of the interconnection 150a. Therefore, undercut regions 161 may be defined at both sides of the blocking dielectric pattern 115b. The undercut regions 161 may be covered with both edge portions of a bottom surface of the interconnection 150a. An air gap 160d between the interconnections 150a may be connected to the undercut region 161. Therefore, the undercut region 161 may be also filled with air. Thus, a parasitic capacitance between the interconnections 150a may be further decreased. A parasitic capacitance between the interconnection 150a and a neighboring conductive pillar 105 may be also minimized.

FIG. 2E is a cross-sectional view taken along line I-I′ of FIG. 1A to illustrate a semiconductor device according to an exemplary embodiment.

Referring to FIG. 2E, a low-k dielectric 157 may be conformally disposed on the sidewalls and top surfaces of the interconnections 150a, and on the contact mold layer 110 between the interconnections 150a. The low-k dielectric 157 may include a dielectric material having a lower dielectric constant than the upper interlayer dielectric 155. For example, when the upper interlayer dielectric 155 includes silicon oxide, the low-k dielectric 157 may include at least one of silicon-oxygen-carbon compound (SiOC) or silicon-oxygen-carbon-hydrogen compound (SiOCH). Both sides and a lower end of an air gap 160e may be enclosed by the low-k dielectric 157.

FIG. 2F is a cross-sectional view taken along lines I-I′ and II-II′ of FIG. 1A to illustrate a semiconductor device according to an exemplary embodiment.

Referring to FIG. 2F, an interconnection 150a′ may be disposed directly on the contact mold layer 110. According to an embodiment, the blocking dielectric pattern 115a disclosed in FIGS. 1B and 1D may not be required. According to an embodiment, a contact part 150c′ connected to the interconnection 150a′ may fill a contact hole 145′ penetrating the contact mold layer 110, and an upper end of the contact part 150c′ may be positioned at the substantially same level as the top surface of the contact mold layer 110. In this case, a first width of the interconnection 150a′ may be substantially the same as a second width of the contact part 150c′, and the contact part 150c′ may have a sidewall self-aligned to a sidewall of the interconnection 150a′. The air gap 160 may disposed between the interconnections 150a′ adjacent to each other. The air gap 160 disclosed in FIG. 2F may be replaced by the air gap 160a of FIG. 2A, the air gap 160b of FIG. 2B, the air gap 160c of FIG. 2C, or the air gap 160e of FIG. 2E.

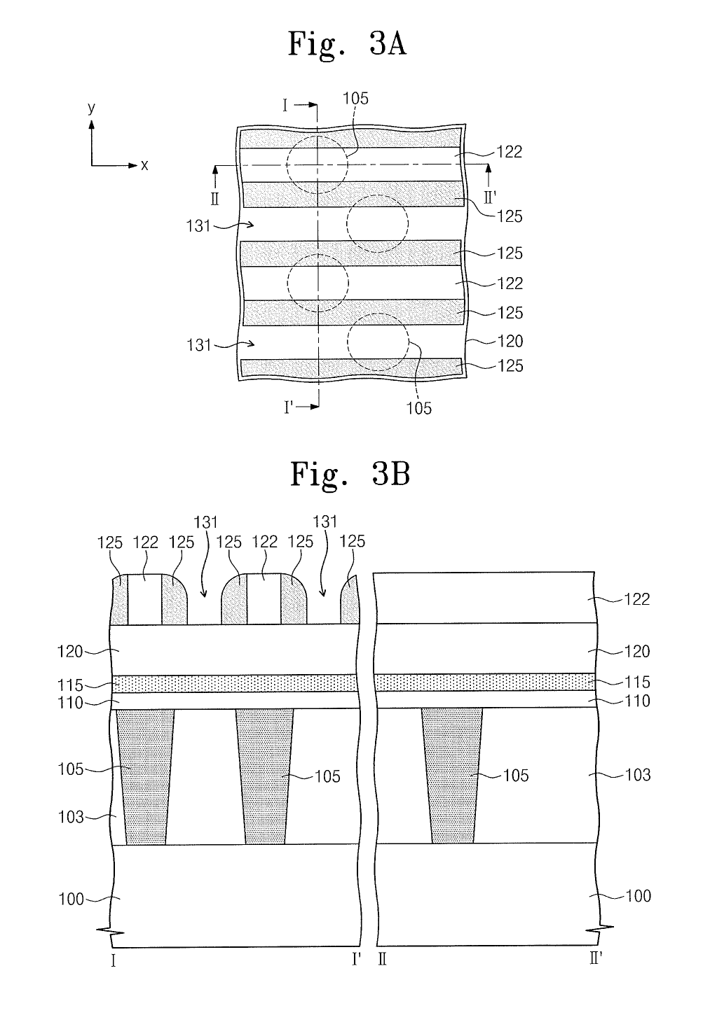

FIGS. 3A to 10A are plan views for describing a method of fabricating a semiconductor device according to an exemplary embodiment, and FIGS. 3B to 10B are cross-sectional views taken along lines I-I′ and II-II′ of FIGS. 3A to 10A, respectively.

Referring to FIGS. 3A and 3B, a lower interlayer dielectric 103 is formed on a substrate 100, and conductive pillars 105 penetrating the lower interlayer dielectric 103 is formed. As described with reference to FIGS. 1A and 1B, the conductive pillars 105 may be arranged in a zigzag shape in a y-axis direction of FIG. 3A. Top surfaces of the conductive pillars 105 may be coplanar with a top surface of the lower interlayer dielectric 103.

A contact mold layer 110, a blocking dielectric 115 and an interconnection mold layer 120 are formed sequentially on the entire surface of the substrate 100. The blocking dielectric 115 may include a dielectric material having an etch selectivity with respect to the contact mold layer 110 and the interconnection mold layer 120. For example, the contact mold layer 110 and the interconnection mold layer 120 may include oxide, and the blocking dielectric 115 may include nitride and/or oxynitride.

Mask line patterns 122 extending in parallel in a first direction may be formed on the interconnection mold layer 120. The mask lines 122 are spaced apart from one another in a second direction perpendicular to the first direction. An interval between the mask line patterns 122 may be greater than a width of each of the mask line patterns 122.

A hard mask layer may be conformally formed on the substrate having the mask line patterns 122. The hard mask layer may be anisotropically blanket-etched until the interconnection mold layer 120 is exposed, to form hard mask patterns 125 on both sidewalls of each of the mask line patterns 122. At this time, a first opening 131 exposing the interconnection mold layer 120 may be formed between the mask line patterns 122 adjacent to each other. The hard mask patterns 125 may be formed in a spacer shape on both sidewalls of the mask line pattern 122, and extend in parallel in the first direction. The hard mask patterns 125 are spaced apart from one another in the second direction. The hard mask pattern 125 has a first sidewall and a second sidewall facing each other. The first opening 131 may be defined by the first sidewalls of the hard mask patterns 125 between the mask line patterns 122 adjacent to each other. The second sidewall of the hard mask pattern 125 may contact the sidewall of the mask line pattern 122. The first sidewall of the hard mask pattern 125 may correspond to a sidewall which is exposed to the blanket anisotropic etch. And the second sidewall of the hard mask pattern 125 may correspond to a sidewall which is not exposed to the blanket anisotropic etch. The first opening 131 extends in the first direction.

The hard mask pattern 125 may include a material having an etch selectivity with respect to the interconnection mold layer 120. The hard mask pattern 125 may include a material having an etch selectivity with respect to the blocking dielectric 115. The mask line pattern 122 may include a material having an etch selectivity with respect to the hard mask pattern 125. The mask line pattern 122 may include a material having an etch selectivity with respect to the interconnection mold layer 120. For example, when the blocking dielectric 115 includes nitride and the interconnection mold layer 120 includes oxide, the mask line pattern 122 may include nitride and/or oxynitride and the hard mask pattern 125 may include a semiconductor material (e.g., polycrystalline silicon or the like).

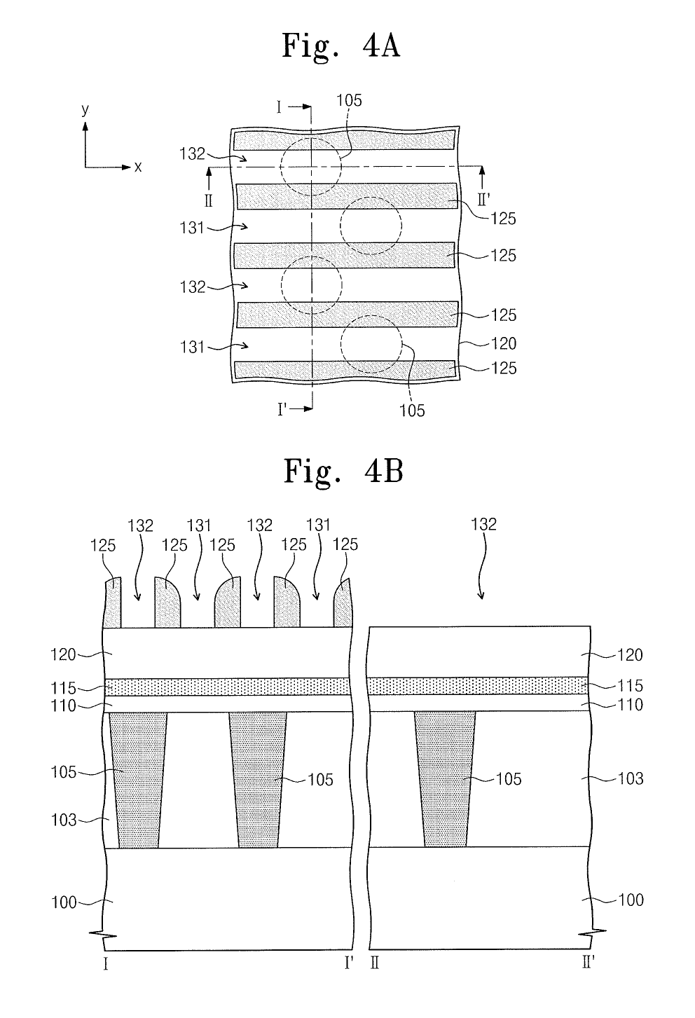

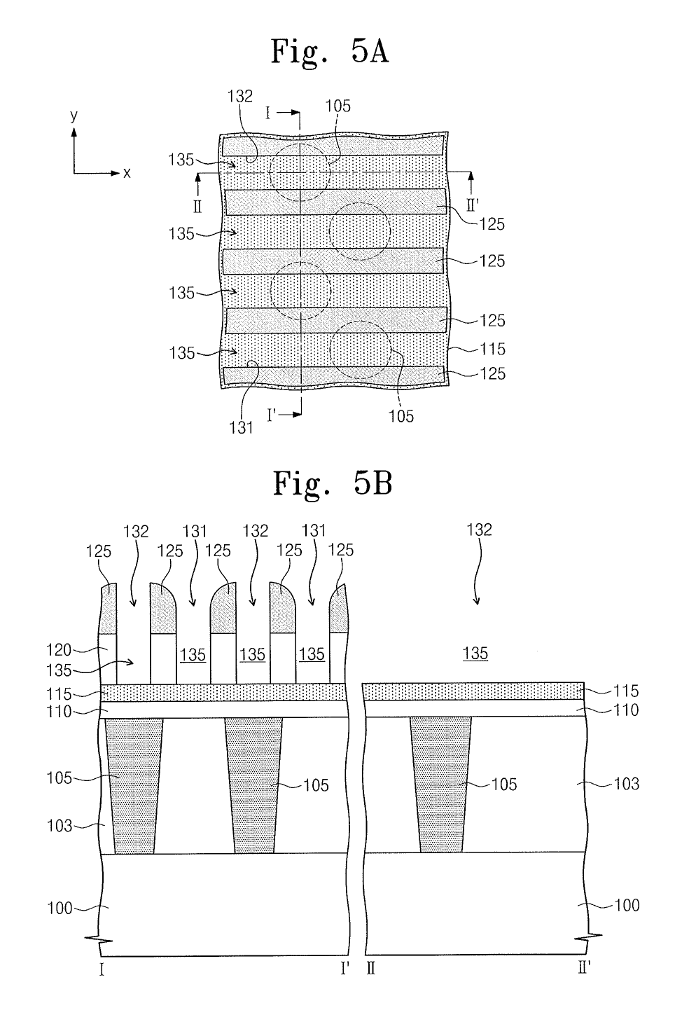

Referring to FIGS. 4A and 4B, a second opening 132 exposing the interconnection mold layer 120 is formed by removing the mask line pattern 122. The second opening 132 is a region where the mask line pattern 122 is removed. The second opening 132 is defined by the second sidewalls of the hard mask patterns 125 on both sidewalls of the mask line pattern 122. The first openings 131 and the second openings 132 may be arranged alternatingly and repeatedly in the second direction.

The width of a bottom surface of the first opening 131 in the second direction may be substantially the same as that of a bottom surface of the second opening 132 in the second direction. According to an embodiment, by adjusting the thickness of the hard mask layer, the widths of the bottom surfaces of the first and second openings 131 and 132 may be formed substantially similar or identical to each other. For example, the interval between the mask line patterns 122 may be greater than the width of the mask line pattern 122. At this time, the thickness of the hard mask layer may be equal to half of a difference between the interval between the mask line patterns 122 and the width of the mask line pattern 122. As such, the widths of the bottom surfaces of the first and second openings 131 and 132 may be formed substantially similar or identical to each other.

Referring to FIGS. 5A and 5B, grooves 135 are formed by etching the interconnection mold layer 120 by using the hard mask patterns 125 as an etch mask. In an embodiment, the blocking dielectric 115 may be used as an etch stop layer. Therefore, each of the grooves 135 may expose the blocking dielectric 115. The grooves 135 are formed under the first and second openings 131, 132, respectively. According to an embodiment, the first openings 131 may define even-numbered grooves among the grooves 135, and the second openings 132 may define odd-numbered grooves among the grooves 135. Each of the grooves 135 may pass over each of the conductive pillars 105. The grooves 135 may extend in parallel in the first direction.

According to an exemplary embodiment, the first and second openings 131, 132 may be formed by using the mask line pattern 122 and the hard mask patterns 125. When the mask line patterns 122 are formed with a minimum line width that can be defined by a photolithography process, each of the first and second openings 131, 132 may be formed with a width less than the minimum line width that can be defined by the photolithography process. Therefore, according to an embodiment, the width of each of the grooves 135 formed by using the first and second openings 131, 132 can be minimized.

According to an embodiment, the hard mask patterns 125 may be formed by forming a hard mask layer on the interconnection mold layer 120 and performing a patterning process with respect to the hard mask layer. In this case, even-numbered and odd-numbered openings defined by the hard mask patterns 125 may be formed at the same time.

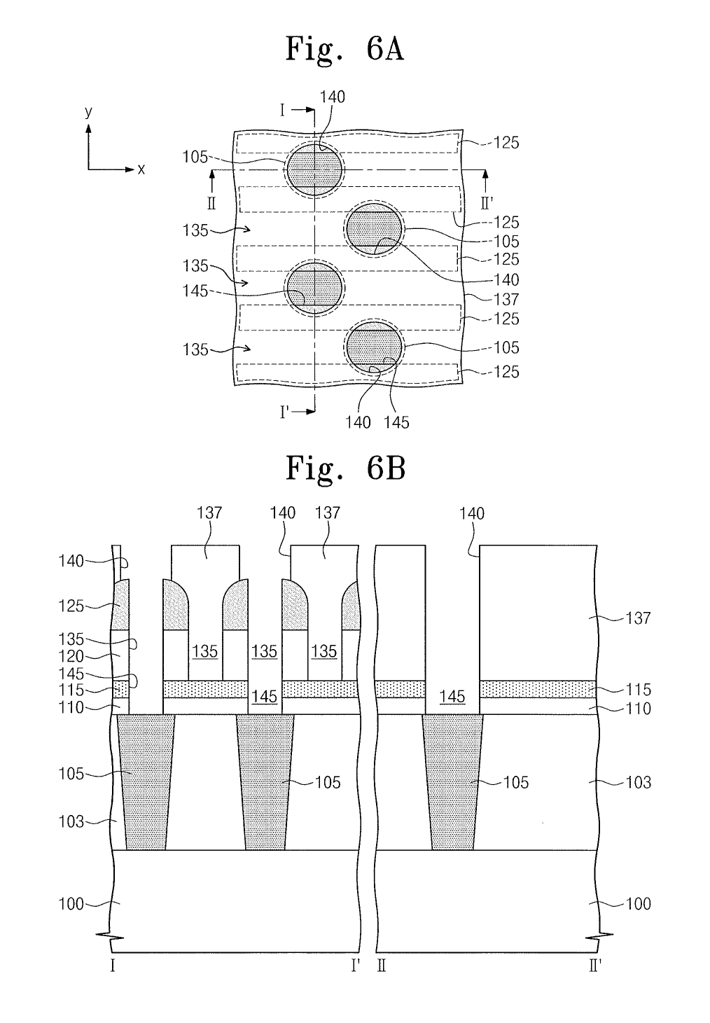

Referring to FIGS. 6A and 6B, a mask layer 137 is formed on the substrate 100 having the hard mask patterns 125 and the grooves 135, and then openings 140 is formed by patterning the mask layer 137. For example, the mask layer 137 may be a photoresist layer. In this case, the openings 140 may be formed by patterning the mask layer 137 using a photolithography process.

Each of the openings 140 may partially expose the blocking dielectric 115 exposed to each of the grooves 135. At this time, the blocking dielectric 115 in the groove 135 exposed by each of the openings 140 may be positioned over the top surface of the conductive pillar 105. That is, each of the openings 140 may be positioned over the top surface of each of the conductive pillars 105. The width of each of the openings 140 in the second direction may be greater than that of each of the grooves 135. Therefore, each of the openings 140 may expose some portions of the hard mask patterns 125.

A contact hole 145 may be formed by continuously etching the exposed blocking dielectric 115 and the contact mold layer 110 by using the mask layer 137 and the exposed hard mask patterns 125 as etch masks.

Since the exposed hard mask patterns 125 are used as an etch mask, the contact hole 145 may include a pair of first inner sidewalls self-aligned to both inner sidewalls of the groove 135. The pair of the first inner sidewalls of the contact hole 145 may be in parallel to the first direction and may be spaced apart from each other in the second direction. Also, the contact hole 145 may include a pair of second inner sidewalls which are self-aligned to some of the opening 140 between the hard mask patterns 125. The pair of the second inner sidewalls of the contact hole 145 may be spaced apart from each other in the first direction. The second inner sidewalls of the contact hole 145 may have a round shape in plan view.

Since the contact hole 145 is formed to be self-aligned to both inner sidewalls of the groove 135, misalignment between the groove 135 and the contact hole 145 can be avoided. In particular, misalignment between the groove 135 and the opening 145 in the second direction or a direction anti-parallel to the second direction can be avoided.

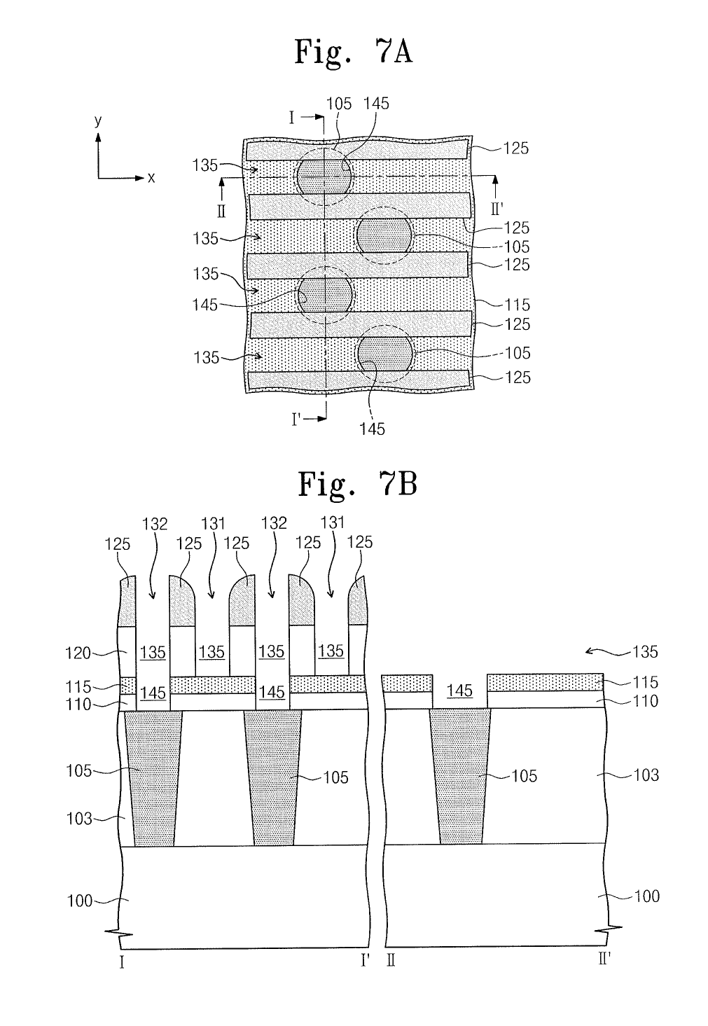

Referring to FIGS. 7A and 7B, the mask layer 137 may be removed. As a result, other portions of the hard mask patterns 125 covered by the mask layer 137 and other portions of the blocking dielectric 115 in the groove 135 covered by the mask layer 137 may be exposed.

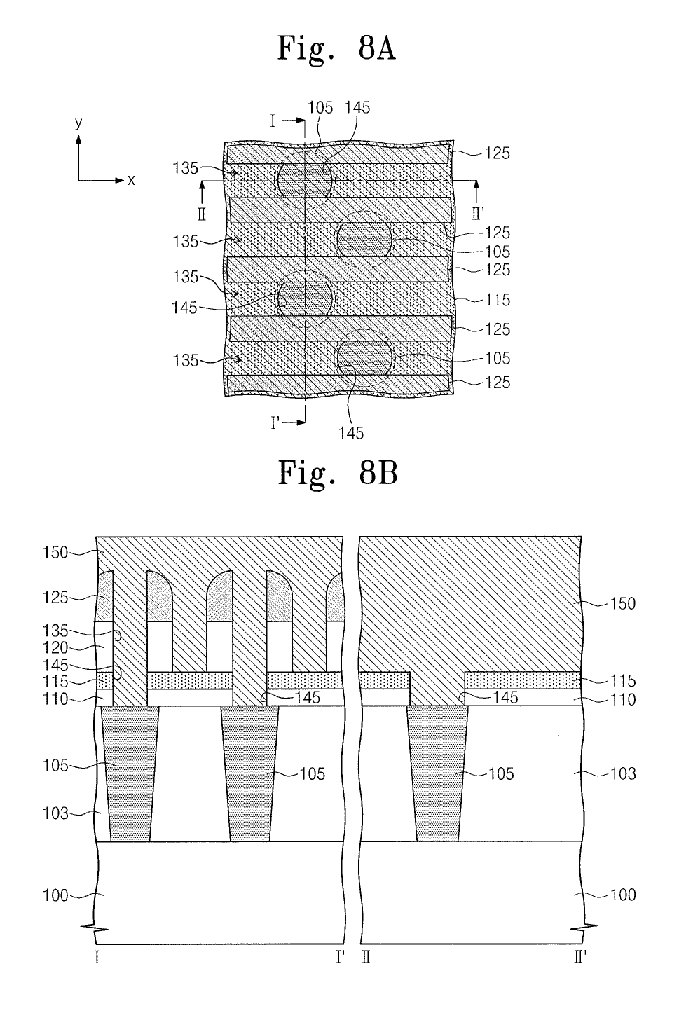

Referring to FIGS. 8A and 8B, a conductive layer 150 filling the contact holes 145 and the grooves 135 may be formed on an entire surface of the substrate 100. The conductive layer 150 may include a metal such as tungsten, aluminum, copper, or the like. In an embodiment, the conductive layer 150 may further include a barrier metal (e.g., titanium nitride, tantalum nitride, or the like) to minimize diffusion of a metal element. In an embodiment, the conductive layer 150 may further include a glue layer such as a titanium layer, a tantalum layer, or the like.

According to an embodiment, as disclosed in FIG. 8B, the conductive layer 150 may be formed in a state that the hard mask pattern 125 remains.

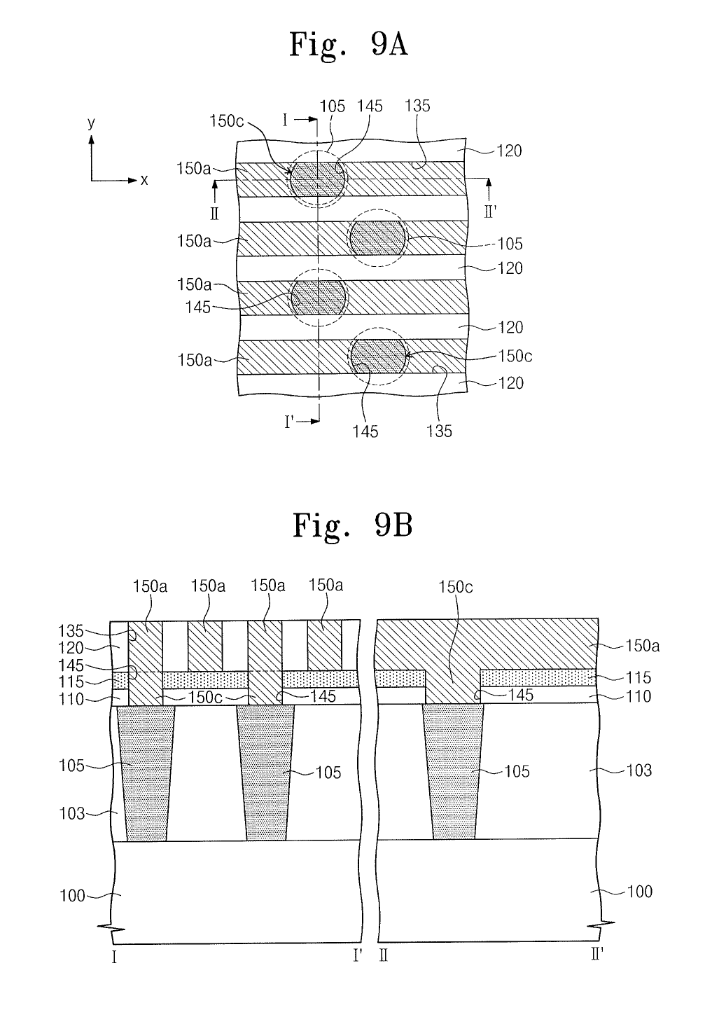

Referring to FIGS. 9A and 9B, a contact part 150c filling the contact hole 145, and an interconnection 150a filling the groove 135 may be formed by planarizing the conductive layer 150 until the interconnection mold layer 120 is exposed. The hard mask patterns 125 may be removed while the conductive layer 150 is planarized. The conductive layer 150 may be planarized by using a chemical and mechanical polishing process.

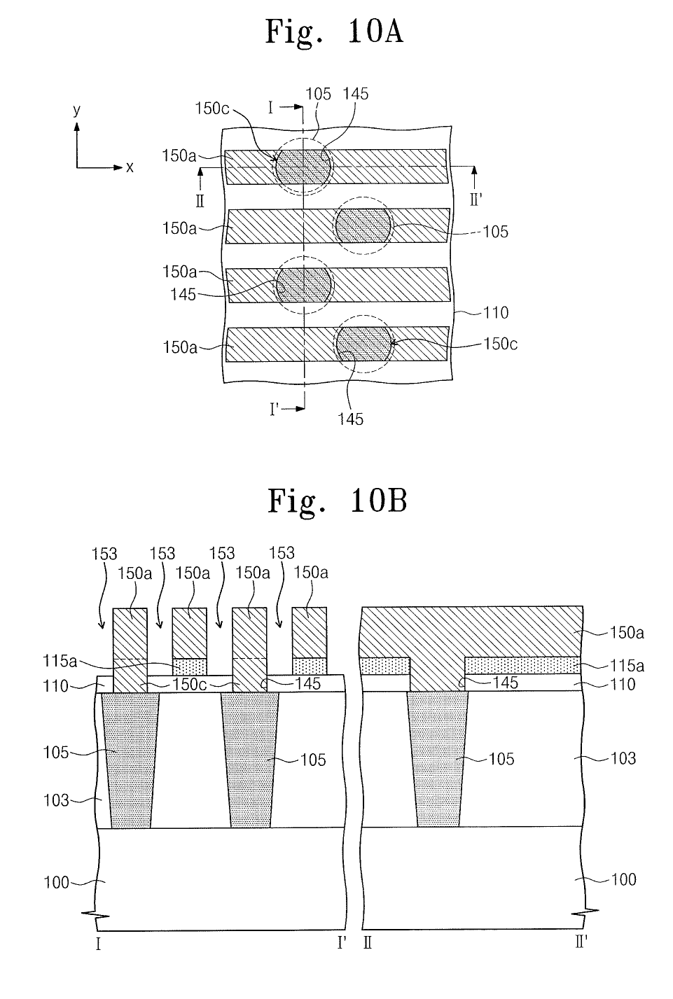

Referring to FIGS. 10A and 10B, the interconnection mold layer 120 and the blocking dielectric 115 between the interconnections 150a may be etched until the contact mold layer 110 is exposed. As such, vacant spaces 153 may be formed between the interconnections 150a. The interconnection mold layer 120 between the interconnections 150a may be removed by using an anisotropic or isotropic etching. According to an embodiment, the blocking dielectric 115 between the interconnections 150a may be removed by using the anisotropic etching. As a result, a blocking dielectric pattern 115a may be formed under each of the interconnections 150a. The blocking dielectric pattern 115a may have a sidewall aligned to a sidewall of the interconnection 150a. As the blocking dielectric 115 between the interconnections 150a is etched, both sidewalls of an upper portion of the contact part 150c may be exposed. The upper portion of the contact part 150c may correspond to a portion of the contact part 150c which is positioned at a higher level than the top surface of the contact mold layer 110. The exposed sidewall of the upper portion of the contact part 150c corresponds to an upper portion of the first sidewall of the contact part 150c.

Next, the upper interlayer dielectric 155 disclosed in FIGS. 1A, 1B and 1D may be formed. At this time, as disclosed in FIGS. 1B and 1D, an air gap 160 may be formed between the interconnections 150a. A method of forming the upper interlayer dielectric 155 and the air gap 160 will be described in more detail with reference to FIGS. 1A, 1B and 1D.

Referring to FIGS. 10A, 10B, 1A, 1B and 1D, the upper interlayer dielectric 155 may be formed with poor step coverage. Therefore, an overhang may occur at an upper end of the vacant space 153, so that the air gap 160 may be formed. According to an embodiment, the upper interlayer dielectric 155 may be formed by using a chemical vapor deposition (CVD) process. The CVD process may have a process pressure of about 50 Torr to atmospheric pressure. When the process pressure of the CVD process is high, e.g., about 50 Torr or more, the step coverage of the upper interlayer dielectric 155 may be poor, so that the air gap 160 may be formed. A process temperature of the CVD process may be lower than a melting point of a conductive material (e.g., metal) contained in the interconnection 150a. According to an embodiment, the CVD process for the upper interlayer dielectric 155 may use thermal energy, plasma energy, or thermal energy/plasma energy. According to an embodiment, the upper interlayer dielectric 155 may be formed by using a single CVD process.

According to an embodiment, the upper interlayer dielectric 155 may be formed by using a multi CVD process. The multi CVD process may include a plurality of CVD processes. According to an embodiment, the multi CVD process may include CVD processes having process temperatures different from each other, and/or CVD processes having source gases different from each other. For example, when the upper interlayer dielectric 155 includes silicon oxide, the multi CVD process may include at least two selected from a middle temperature CVD process, a high temperature CVD process, a TEOS-CVD process, a SiH₄-CVD process, Si₂H₆-CVD process, or a Si₂Cl₂H₂-CVD process. The TEOS-CVD process indicates a CVD process using TEOS gas and oxygen source gas, and the SiH₄-CVD process indicates a CVD process using SiH₄ gas and oxygen source gas. According to an embodiment, the Si2H6-CVD process indicates a CVD process using Si₂H₆ gas and oxygen source gas, and the Si₂Cl₂H₂-CVD process indicates a CVD process using Si₂Cl₂H₂ gas and oxygen source gas. The TEOS-CVD process, the SiH₄-CVD process, the Si₂H₆-CVD process, and the Si₂Cl₂H₂-CVD process may use thermal energy and/or plasma energy. Each of the CVD processes included in the multi CVD process may be performed under a process pressure ranging from about 50 Torr to atmospheric pressure. According to an embodiment, the upper interlayer dielectric 155 may further include an oxide (e.g., ALD oxide) formed by an ALD process which is performed before the single CVD process or the multi CVD process is performed.

According to an embodiment, the upper interlayer dielectric 155 may include an ALD oxide, an oxide formed by the SiH₄-CVD process, an oxide formed by the Si₂Cl₂H₂-CVD process, and an oxide formed by the high temperature CVD process. In this case, the air gap 160 disclosed in FIGS. 1B and 1D may be formed between the interconnections 150a. However, embodiments are not limited thereto. The air gap 160 may be formed by another combination of the CVD processes that may be included in the foregoing multi CVD process.

According to an embodiment, while the upper interlayer dielectric 155 is formed by using the multi CVD process, the air gap 160a of FIG. 2A, the air gap 160b of FIG. 2B, the air gap 160d of FIG. 2D, or the air gap 160e of FIG. 2E may be realized by adjusting deposition rates of the CVD processes included in the multi CVD process, and thicknesses of oxides. For example, in the case where the upper interlayer dielectric 155 includes an oxide formed by the Si₂H₆-CVD process, an oxide formed by the Si₂Cl₂H₂-CVD process, and an oxide formed by the high temperature CVD process, the air gap 160a of FIG. 2A may be formed. However, embodiments are not limited thereto. The air gap 160a of FIG. 2A may be formed by another combination of the CVD processes that may be included in the foregoing multi CVD process. The step coverage of the upper interlayer dielectric 155 in FIG. 1B may be worse than that of the upper interlayer dielectric 155 in FIG. 2B.

According to an embodiment, the upper interlayer dielectric 155 may include an ALD oxide, an oxide formed by the TEOS-CVD process using plasma, and an oxide formed by the high temperature CVD process. In this case, the air gap 160c disclosed in FIG. 2C may be realized. For example, as the thickness of the oxide formed by the TEOS-CVD process using the plasma in the upper interlayer dielectric 155 increases, a level of the upper end of the air gap 160c in FIG. 2C may be higher. However, embodiments are not limited thereto. The air gap 160c of FIG. 2C may be formed by another combination of the CVD processes that may be included in the multi CVD process.

When the vacant spaces 153 between the interconnections 150a expose an upper portion of the contact part 150c, the lower end of the air gap 160 may be positioned at a lower level than the bottom surface of the interconnection 150a.

According to an embodiment, after the upper interlayer dielectric 155 is formed, the air gap is formed between the interconnections 150a. Therefore, the parasitic capacitance between the interconnections 150a may be minimized. Also, the contact hole 145 may be formed self-aligned to the inner sidewall of the groove 135. Therefore, misalignment between the groove 135 and the contact hole 145 can be prevented. Accordingly, a process margin for the fabrication of a semiconductor device may be improved. Also, the space between the contact holes 145 and the groove 135 is minimized.

According to a method of fabricating a semiconductor device described with reference to FIGS. 10A and 10B, the blocking dielectric 115 between the interconnections 150a may be removed by an anisotropic etching. According to an embodiment, the blocking dielectric 115 between the interconnections 150a may be removed by an isotropic etching. In this case, as disclosed in FIG. 2D, the width of the blocking dielectric pattern 115b is less than that of the interconnection 150a and thus the undercut region 161 may be formed.

Before the upper interlayer dielectric 155 is formed, the low-k dielectric 157 disclosed in FIG. 2E may be formed conformally on the substrate 100 having the vacant space 153 between the interconnections 150a. The low-k dielectric 157 may be formed by a chemical vapor deposition process or atomic layer deposition process having superior step coverage. After forming the low-k dielectric 157, the air gaps may be formed between the interconnections 150a by forming the upper interlayer dielectric 155.

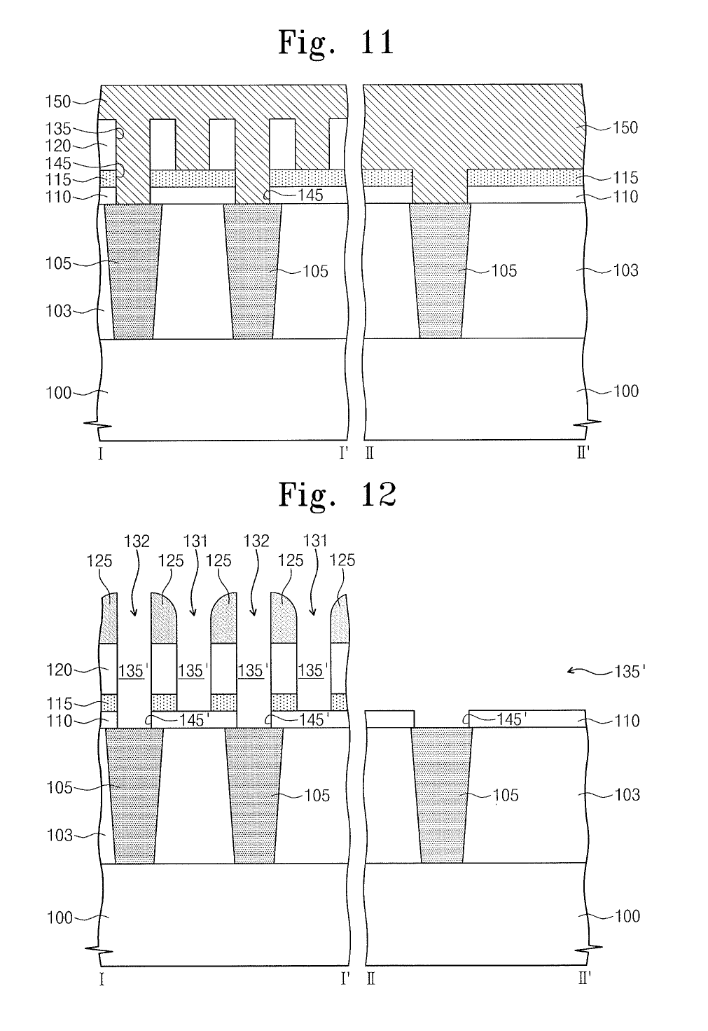

In a method of fabricating a semiconductor device, as disclosed in FIG. 8B, the conductive layer 150 may be formed in a state that the hard mask patterns 125 are left. According to an embodiment, as illustrated in FIG. 11, after the hard mask patterns 125 are removed, the conductive layer 150 filling the groove 135 and the contact hole 145 may be formed on the substrate 100. Subsequent fabrication processes may be the same as the processes described with reference to FIGS. 9A, 9B, 10A and 10B and the processes of forming the upper interlayer dielectric 155.

In a method of fabricating a semiconductor device, before the conductive layer 150 is formed, a process of removing the blocking dielectric 115 exposed to the groove 135 may be further performed. This process will be described in more detail with reference to FIG. 12.

FIG. 12 is a schematic sectional view for describing a method of fabricating a semiconductor device according to an exemplary embodiment of.

Referring to FIGS. 7B and 12, after the contact hole 145 is formed and the mask layer (see 137 of FIG. 6B) is removed, the blocking dielectric 115 exposed in the groove 135 may be etched until the contact mold layer 110 under the groove 135 is exposed. As a result, a groove 135′ exposing the contact mold layer 110 may be formed. Also, a contact hole 145′ may be formed confinedly in the contact mold layer 110. That is, an upper end of the contact hole 145′ may be positioned at the substantially same level as the top surface of the contact mold layer.

Next, the conductive layer 150 illustrated in FIGS. 9A and 9B may be formed. In this case, the conductive layer 150 may fill the groove 135′ and the contact hole 145′. Subsequent fabrication processes may be the same as the processes described with reference to FIGS. 10A and 10B and the process of forming the upper interlayer dielectric 155. The semiconductor device fabricated according to the current example may be realized by the semiconductor device described with reference to FIG. 2F. The semiconductor device disclosed in FIG. 2F may not include the blocking dielectric. According to an embodiment, the blocking dielectric 115 may be removed. Therefore, hydrogen atoms that may be included in the lower interlayer dielectric 103 may be easily extracted to the outside of the semiconductor device. In an embodiment, the blocking dielectric 115 that may include hydrogen atoms may be removed.

Meanwhile, according to a method of fabricating a semiconductor device described with reference to FIGS. 3A to 10A and FIGS. 3B to 10B, after the groove 135 is formed, the mask layer 137 having the opening 140 defining the contact hole 145 may be formed.

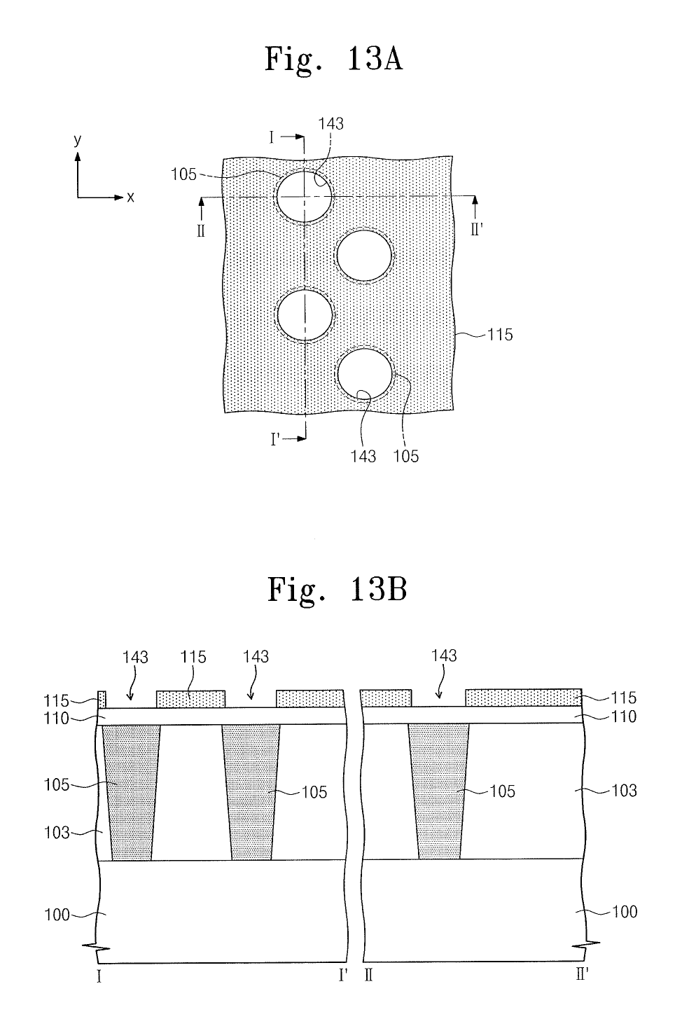

FIGS. 13A to 16A are plan views for describing a method of fabricating a semiconductor device according to an exemplary embodiment of, and FIGS. 13B to 16B are cross-sectional views taken along lines I-I′ and II-II′ of FIGS. 13A to 16A.

Referring to FIGS. 13A and 13B, a lower interlayer dielectric 103 may be formed on a substrate 100, and conductive pillars 105 penetrating the lower interlayer dielectric 103 may be formed. Thereafter, a contact mold layer 110 may be formed on the lower interlayer dielectric 103.

A blocking dielectric 115 may be formed on the contact mold layer 110. Thereafter, guide holes 143 exposing the contact mold layer 110 may be formed by patterning the blocking dielectric 115. The guide holes 143 may be formed over top surfaces of the conductive pillars 105, respectively. According to an embodiment, widths of the guide hole 143 in first and second directions may be respectively less than those of the top surface of the conductive pillar 105 in the first and second directions. However, embodiments are not limited thereto.

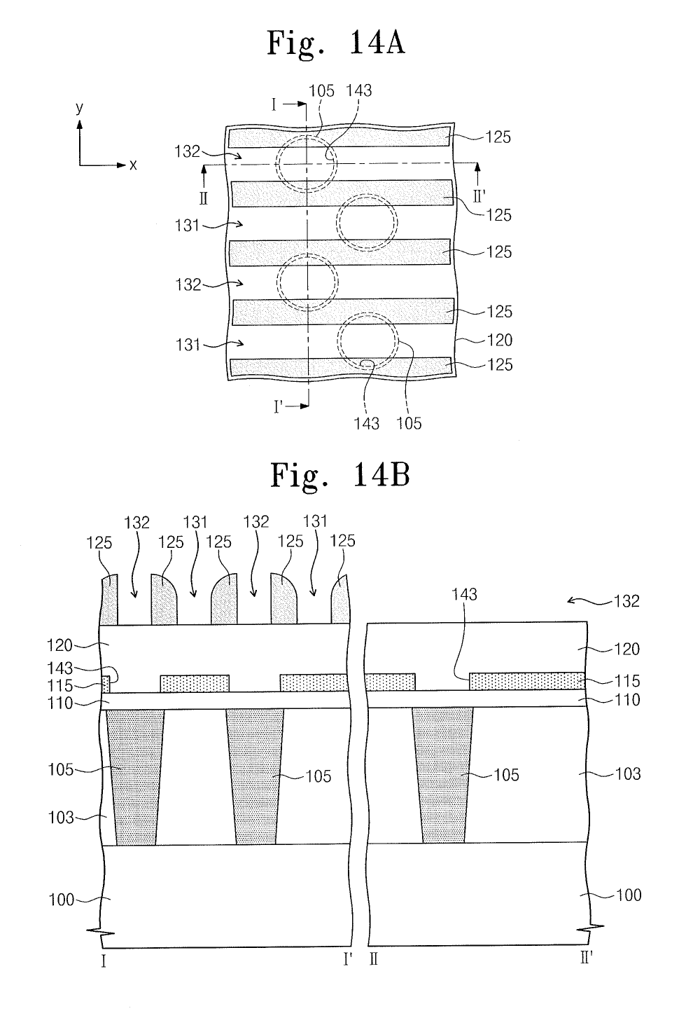

Referring to FIGS. 14A and 14B, an interconnection mold layer 120 may be formed on the substrate 100 having the guide holes 143. The interconnection mold layer 120 may fill the guide holes 143. Hard mask patterns 125 extending in parallel in the first direction may be formed on the interconnection mold layer 120. The hard mask patterns 125 define first and second openings 131, 132. The hard mask patterns 125 may be formed by the same method as that described with reference to FIGS. 3A, 3B, 4A and 4B.

According to an embodiment, the width of the guide hole 143 in the second direction (i.e., y-axis direction of FIG. 14A) may be greater than that of the first opening 131 in the second direction. Likewise, the width of the guide hole 143 in the second direction may be greater than that of the second opening 132 in the second direction.

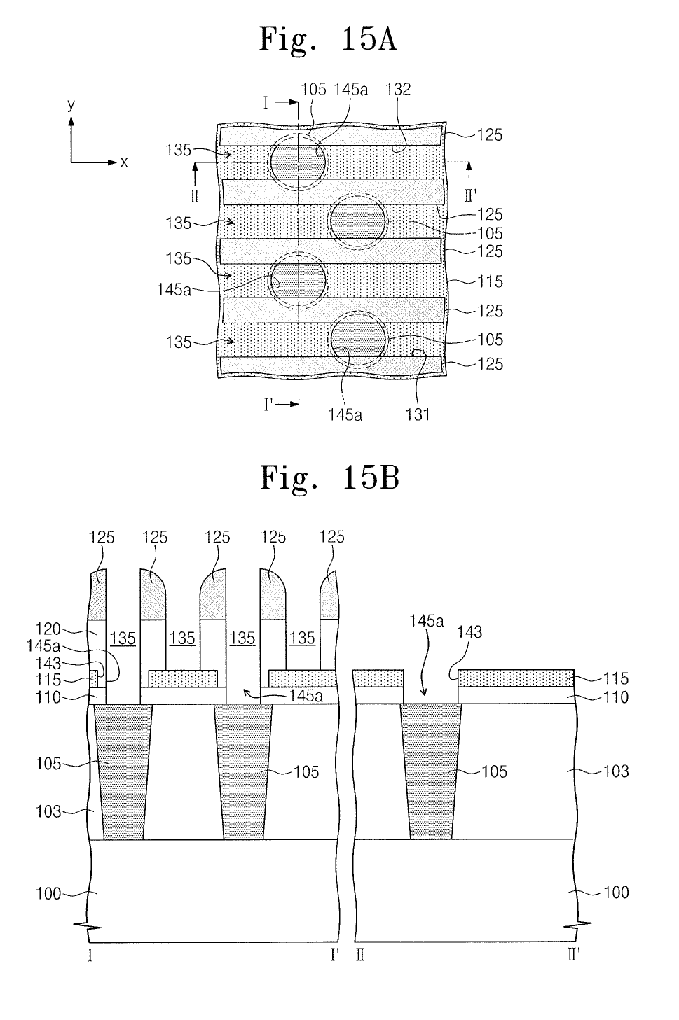

Referring to FIGS. 15A and 15B, the interconnection mold layer 120 and the contact mold layer 110 are continuously etched by using the hard mask patterns 125 and the blocking dielectric 115 as an etch mask. As a result, a groove 135 and a contact hole 145a are formed. The groove 135 may expose the blocking dielectric 115, and the contact hole 145a may continuously penetrate a portion of the interconnection mold layer 120 filling the guide hole 143, and the contact mold layer 110 to expose the top surface of the conductive pillar 120. By using the hard mask pattern 125 as an etch mask, the contact hole 145a may have a pair of first inner sidewall self-aligned to inner sidewalls of the groove 135, respectively. The first inner sidewalls of the contact hole 145a may be in parallel to the first direction. Also, the contact hole 145a may have a pair of second inner sidewalls self-aligned to some portions of a sidewall of the guide hole 143 between both inner sidewalls of the groove 135. The pair of second inner sidewalls of the contact hole 145a may be spaced apart from each other in the first direction.

Since the groove 135 and the contact hole 145a are formed by using the hard mask patterns 125, misalignment between the groove 135 and the contact hole 145a may not occur. Therefore, a process margin for the fabrication of a semiconductor device may be improved.

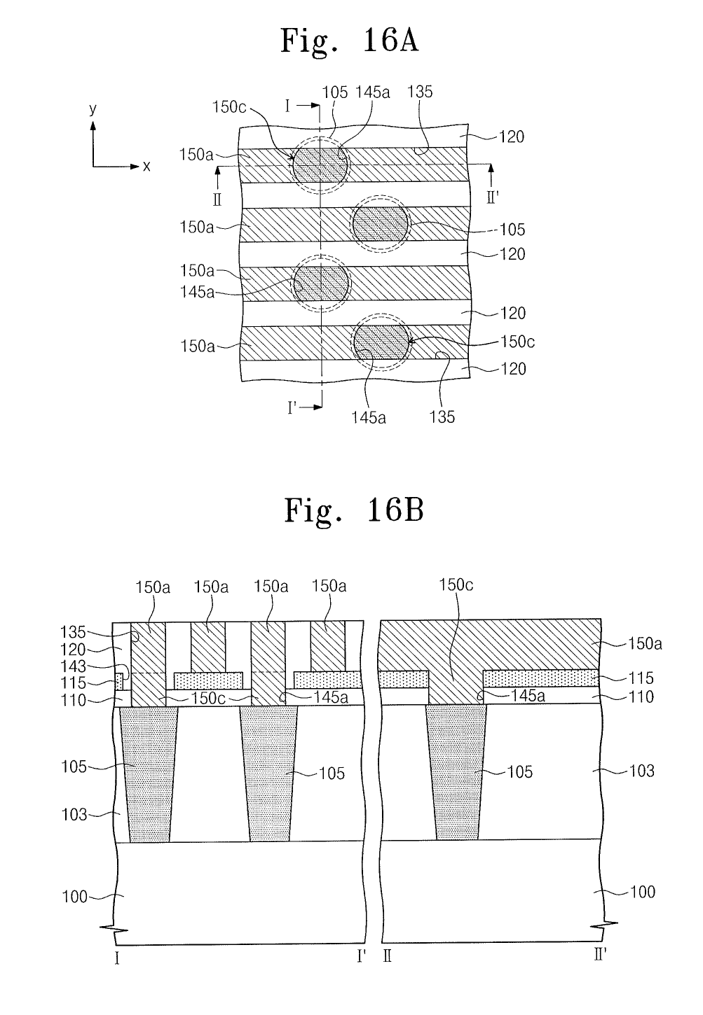

Referring to FIGS. 16A and 16B, thereafter, a conductive layer filling the groove 135 and the contact hole 145a may be formed and be then planarized until the interconnection mold layer 120 is exposed, to form a contact part 150c filling the contact hole 145a, and an interconnection 150a filling the groove 135. The conductive layer may be formed in a state that the hard mask patterns 125 are left. In this case, the hard mask patterns 125 may be removed by the process of planarizing the conductive layer. According to an embodiment, after the hard mask patterns 125 are removed, the conductive layer may be formed.

After the interconnection 150a and the contact part 150c are formed, the interconnection mold layer 120 and the blocking dielectric 115 between the interconnections 150a may be etched until the contact mold layer 110 is exposed. As a result, the vacant spaces 153 between the interconnections 150a disclosed in FIGS. 10A and 10B may be formed. Thereafter, by performing the same process as the foregoing process of forming the upper interlayer dielectric 155, the air gap may be formed between the interconnections 150a.

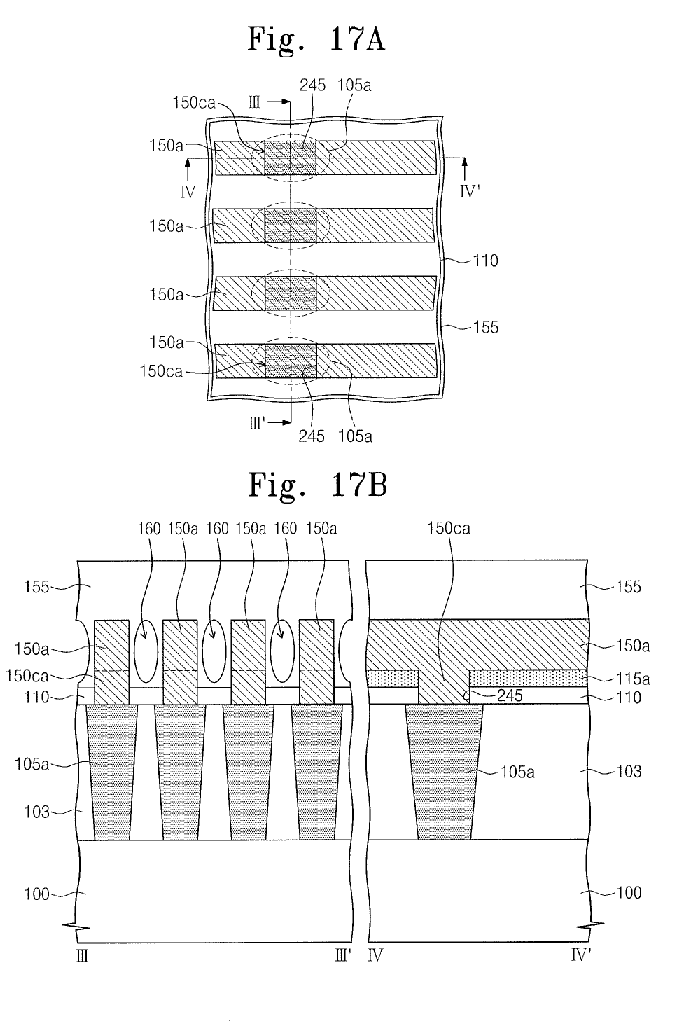

FIG. 17A is a plan view illustrating a semiconductor device according to an exemplary embodiment, and FIG. 17B is a cross-sectional view taken along lines III-III′ and IV-IV′ of FIG. 17A.

Referring to FIGS. 17A and 17B, a plurality of conductive pillars 105a may penetrate a lower interlayer dielectric 103 on a substrate 100. As disclosed in FIG. 17A, the conductive pillars 105a may be arranged in one direction to form one column. Top surfaces of the conductive pillars 105a may be coplanar with a top surface of the lower interlayer dielectric 103. The conductive pillars 105a may comprise the same material as the conductive pillar 105 of the foregoing first embodiment.

A contact mold layer 110 may be disposed on the lower interlayer dielectric 103. A plurality of interconnections 150a may extend in parallel in a first direction on the contact mold layer 110 and may be spaced apart from one another in a second direction perpendicular to the first direction. The first direction may correspond to an x-axis direction of FIG. 17A, and the second direction may correspond to a y-axis direction of FIG. 17A. A contact part 150ca extends downwardly from some portion of a bottom surface of each of the interconnections 150a to penetrate the contact mold layer 110. Each of the contact parts 150ca may contact the top surface of each of the conductive pillars 105a. As disclosed in FIG. 17A, the contact parts 150ca connected to the interconnections 150a may be arranged in the second direction to form one column.

A width of the contact part 150ca in the second direction may be substantially the same as that of the interconnection 150a in the second direction. According to an embodiment, as disclosed in FIG. 17A, a bottom surface of the contact part 150ca may have a quadrangle shape. The contact part 150ca may include a pair of first sidewalls respectively self-aligned to both sidewalls of the interconnection 150a thereon. The pair of first sidewalls of the contact part 150ca may extend in the first direction, and may be spaced apart from each other in the second direction. Also, the contact part 150ca may further include a pair of second sidewalls extending in the second direction. The pair of second sidewalls of the contact part 150ca may be spaced apart from each other in the first direction.

A blocking dielectric pattern 115a may be disposed between the interconnection 150a and the contact mold layer 110. In this case, the contact part 150ca may be projected to a higher level than the top surface of the contact mold layer 110. The blocking dielectric pattern 115a may have a sidewall self-aligned to the sidewall of the interconnection 150a. According to an embodiment, the blocking dielectric pattern 115a may have a width which is less than that of the interconnection 150a, and undercut regions may be defined at both sides of the blocking dielectric pattern 115a.

According to an embodiment, the blocking dielectric pattern 115a may be omitted. In this case, the interconnection 150a may be disposed directly on the contact mold layer 110, and the upper end of the contact part 150ca may be positioned at the substantially same level as the top surface of the contact mold layer 110.

An upper interlayer dielectric 155 may be disposed on the interconnections 150a. At this time, air gaps 160 may be formed between the interconnections 150a. The air gaps 160 may be replaced by any one of the air gaps 160a of FIG. 2A, the air gaps 160b of FIG. 2B, the air gaps 160c of FIG. 2C, the air gaps 160d of FIG. 2D, or the air gap 160e of FIG. 2E.

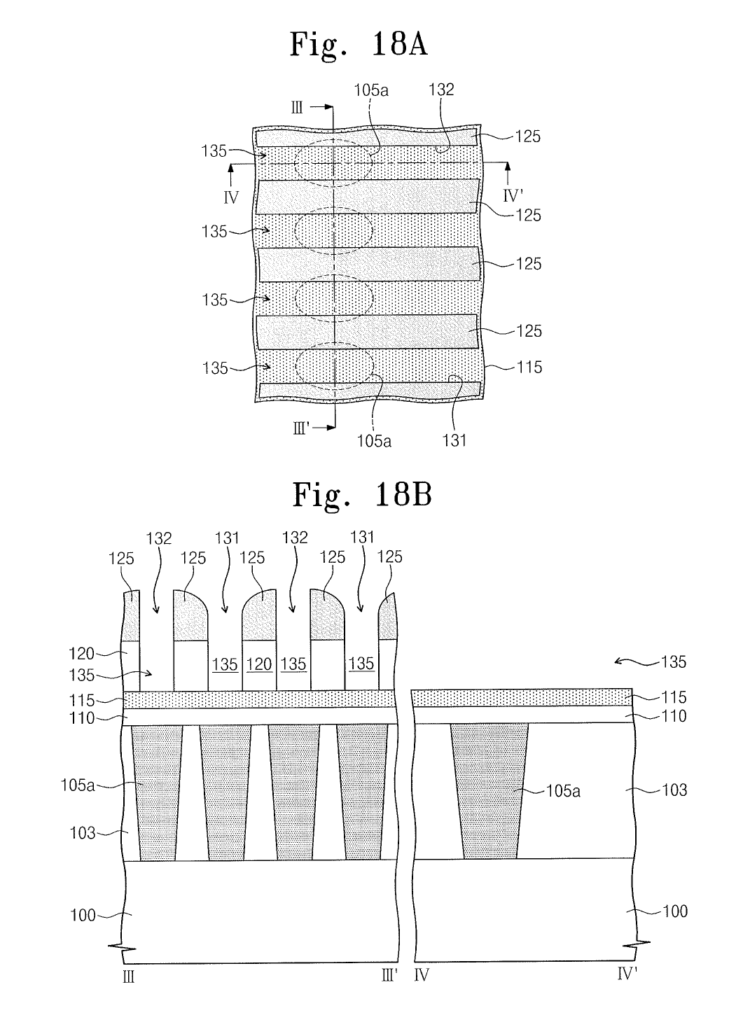

FIGS. 18A to 22A are plan views for describing a method of fabricating a semiconductor device according to an exemplary embodiment, and FIGS. 18B to 22B are cross-sectional views taken along lines III-III′ and IV-IV′ of FIGS. 18A to 22A, respectively.

Referring to FIGS. 18A and 18B, a lower interlayer dielectric 103 may be formed on a substrate, and conductive pillars 105a penetrating the lower interlayer dielectric 103 may be formed. The conductive pillars 105a may be arranged in one direction to form one column.

A contact mold layer 110, a blocking dielectric 115, and an interconnection mold layer 120 may be sequentially formed on the conductive pillars 105a and the lower interlayer dielectric 103. Hard mask patterns 125 extending in parallel in a first direction may be formed on the interconnection mold layer 120. The hard mask patterns 125 may define first openings 131 and second openings 132 which are alternatingly and repeatedly arranged in a second direction perpendicular to the first direction. The first and second openings 131 and 132 may extend in parallel in the first direction. The hard mask patterns 125 may be formed by the same method as the foregoing method of the first embodiment. The conductive pillars 105a may be arranged in the second direction to form one column.

Grooves 135 may be formed by etching the interconnection mold layer 120 by using the hard mask patterns 125 as an etch mask. At this time, the blocking dielectric 115 may be used as an etch stop layer. The grooves 135 may extend in parallel in the first direction, and each of the grooves 135 may pass over each of the conductive pillars 105a. A width of the conductive pillar 105a in the second direction may be greater than that of each of the grooves 135 in the second direction.

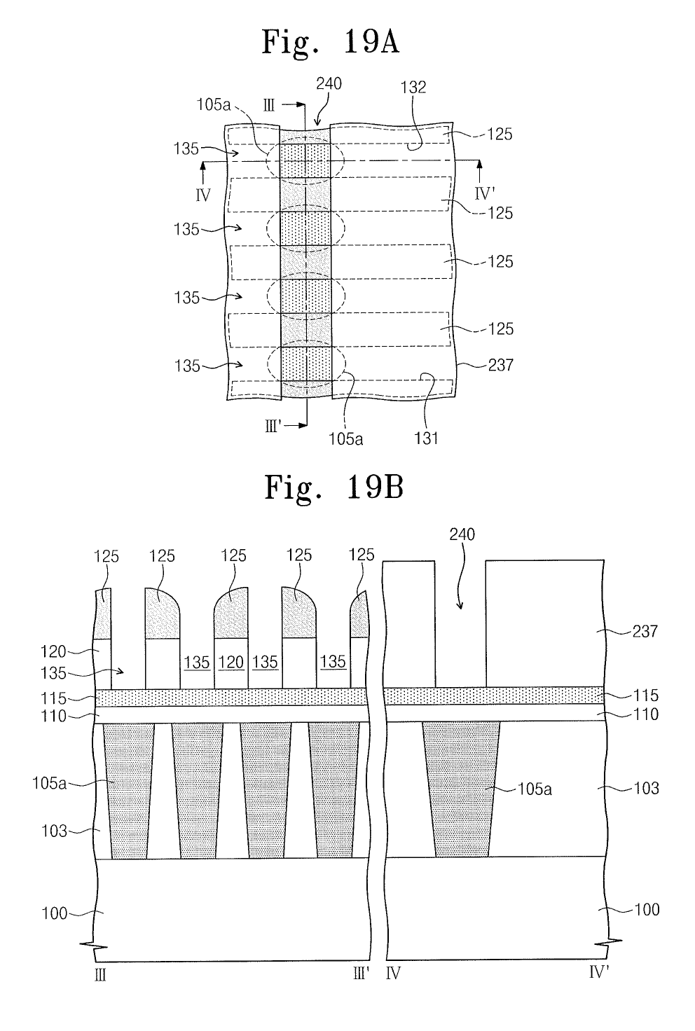

Referring to FIGS. 19A and 19B, a mask layer 237 may be formed on the substrate 100 having the grooves 135 and the hard mask patterns 125, and then an opening 240 may be formed by patterning the mask layer 237. The opening 240 may extend in the second direction to cross the hard mask patterns 125 and the grooves 135. That is, the opening 240 may have a line shape extending in the second direction. The opening 240 may expose some portions of the grooves 135, and some portions of the hard mask patterns 125. A crossing region between the opening 240 and each of the grooves 135 may correspond to a region where a contact hole is formed. Some portion of the blocking dielectric 115, positioned at the crossing region between the opening 240 and each of the grooves 135, may be exposed. The exposed portion of the blocking dielectric 115 at the crossing region may be disposed over the conductive pillar 105a.

The mask layer 237 may be a photoresist layer. The mask layer 237 may be patterned by a photolithography process to form the opening 240. The photolithography process may include an exposure process and a development process.

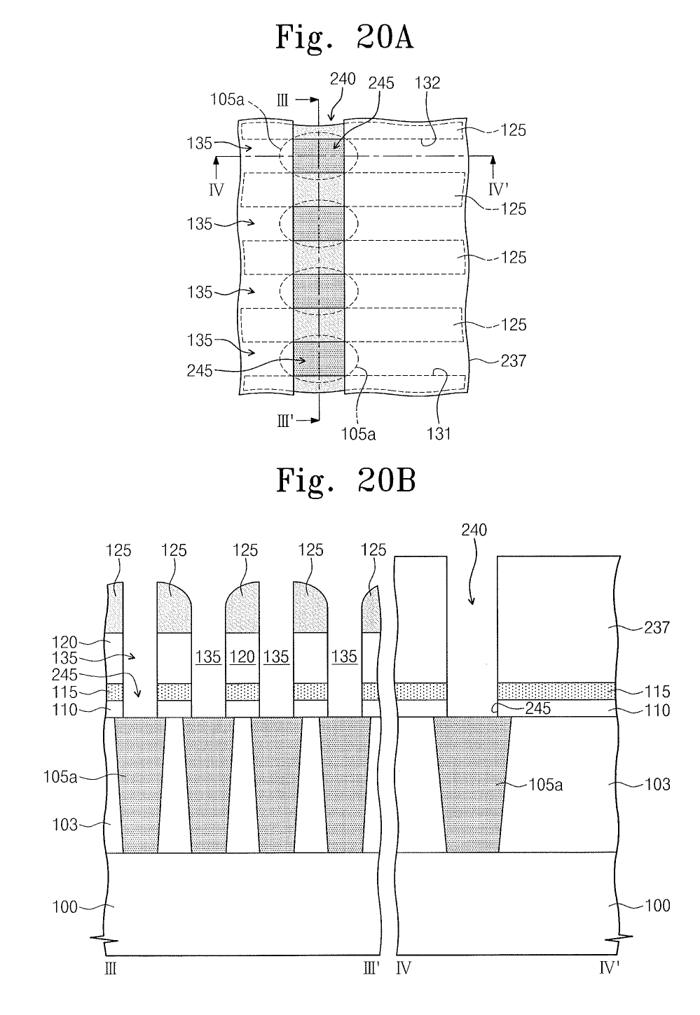

Referring to FIGS. 20A and 20B, contact holes 245 may be formed by continuously etching the exposed portions of the blocking dielectric 115, and the contact mold layer 110 by using the mask layer 237 and the hard mask patterns 125 as an etch mask. The contact holes 245 may expose the conductive pillars, respectively. Due to the hard mask patterns 125 extending in the first direction and the opening 240 extending in the second direction, a bottom surface of each of the contact holes 245 may be formed in a quadrangle shape. By using the hard mask patterns 125 defining the groove 135 as an etch mask, the contact hole 245 may include a pair of first inner sidewalls respectively self-aligned to both inner sidewalls of the groove 135. The first inner sidewalls of the contact hole 245 may extend in parallel in the first direction. Also, the contact holes 245 may include a pair of second inner sidewalls respectively self-aligned to both sidewalls of the opening 240. The second inner sidewalls of the contact hole 245 may extend in parallel in the second direction.

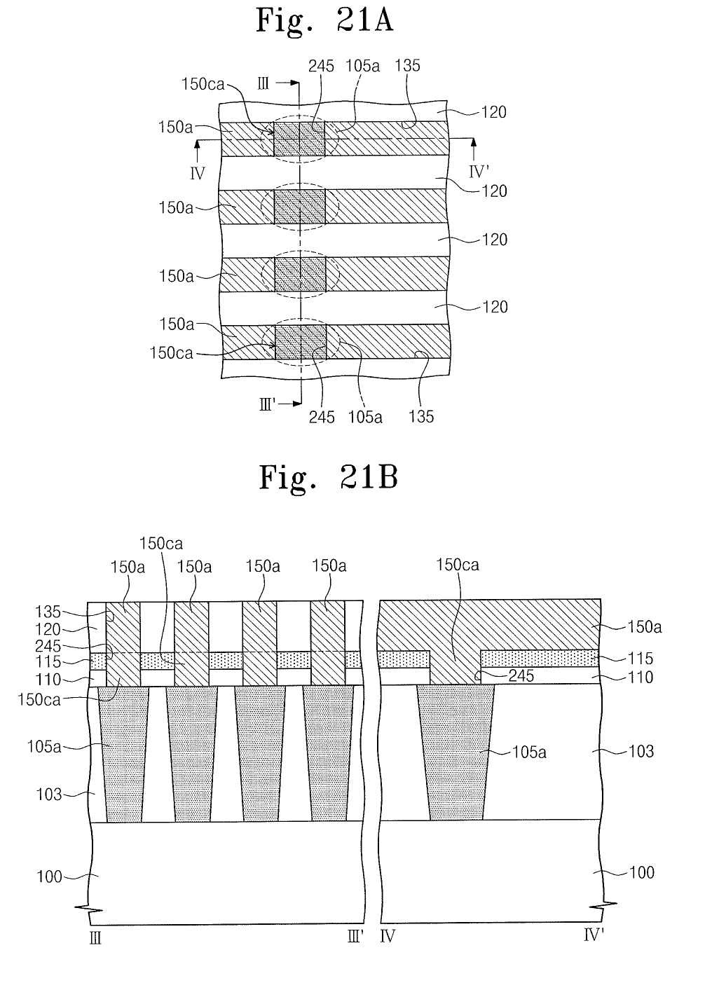

Referring to FIGS. 21A and 21B, thereafter, the mask layer 237 may be removed, and then a conductive layer filling the grooves 135 and the contact holes 245 may be formed on the substrate 100. The conductive layer may be formed in a state that the hard mask patterns 125 remain. According to an embodiment, the conductive layer may be formed after the hard mask patterns 125 are completely removed.

A contact part 150ca filling the contact hole 245 and a interconnection 150a filling the groove 135 may be formed by planarizing the conductive layer until the interconnection mold layer 120 is exposed.

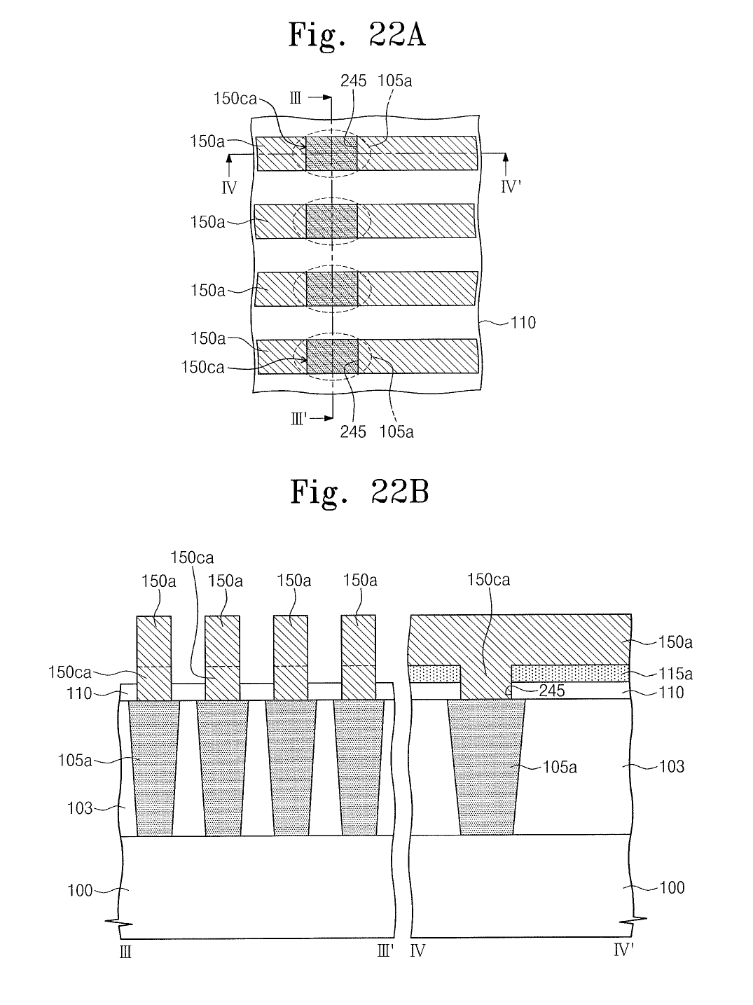

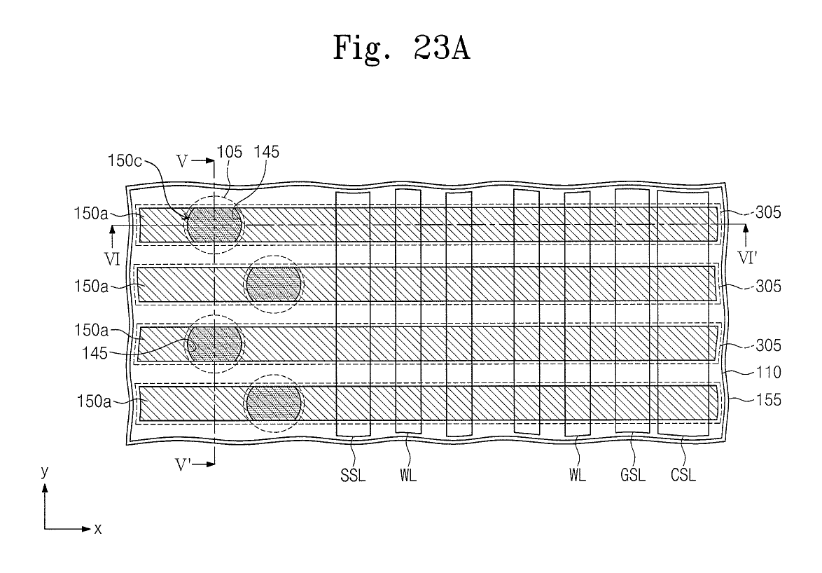

Referring to FIGS. 22A and 22B, next, the interconnection mold layer 120 and the blocking dielectric 115 between the interconnections 150a may be removed. Therefore, vacant spaces may be formed between the interconnections 150a.

Thereafter, the upper interlayer dielectric 155 of FIGS. 17A and 17B may be formed such that an air gap is formed between the interconnections 150a. The process of forming the upper interlayer dielectric 155 may be performed by the same process as that of the first embodiment. The air gap 160 between the interconnections 150a may be realized by any one of the air gaps of FIGS. 2A to 2E.

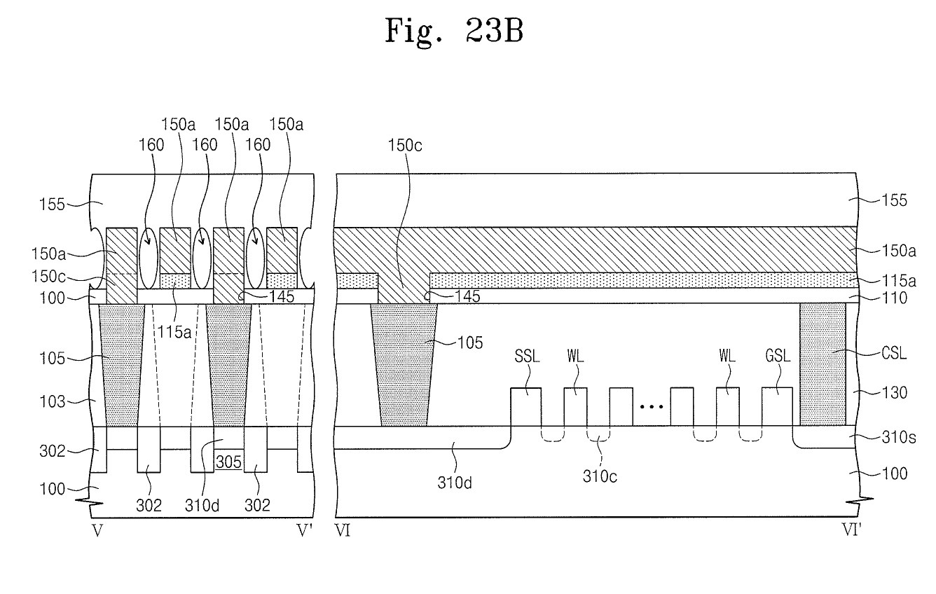

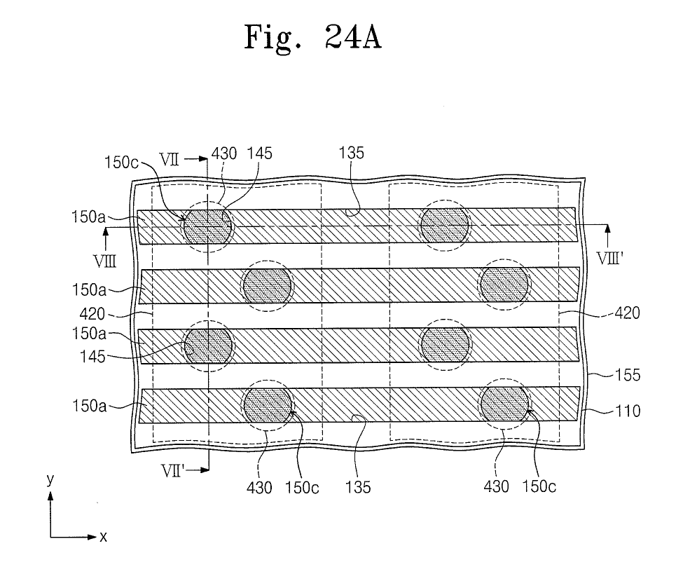

FIG. 23A is a plan view illustrating a semiconductor device according to an exemplary embodiment, and FIG. 23B is a cross-sectional view taken along lines V-V′ and VI-VI′ of FIG. 23A.

Referring to FIGS. 23A and 23B, a device isolation pattern 302 may be disposed in a substrate 100 to define active regions 305. The active region 305 may correspond to a portion of the substrate 100 surrounded by the device isolation pattern 302. The active regions 305 may extend in parallel in a first direction. The active regions 305 may be spaced apart from one another in a second direction perpendicular to the first direction. The first direction may correspond to an x-axis direction of FIG. 23A, and the second direction may correspond to a y-axis direction of FIG. 23A. The active regions 305 may be doped with first conductive type dopants.

A string select line SSL and a ground select line GSL may extend in parallel in the second direction to cross the active regions 305. A plurality of word lines WL may be disposed between the string select line SSL and the ground select line GSL. The word lines WL may extend in parallel in the second direction to cross the active regions 305. A common drain 310d may be disposed in each of the active regions 305 at one side of the string select line SSL, and a common source 310s may be disposed in each of the active regions 305 at one side of the ground select line GSL. The string select line SSL, the word lines WL and the ground select line GSL may be disposed between the common drain 310d and the common source 310s. A cell source/drains 310c may be disposed in the active region 305 at both sides of the word line WL. The common drain 310d and the common source 310s may be doped with second conductive type dopants. The cell source/drains 310c may be doped with the second conductive type dopants. According to an embodiment, the cell source/drain 310c may be an inversion region generated by a fringe field of the word line WL when an operation voltage is applied to the word line WL.

The word line WL may include a tunnel dielectric, a charge storage layer, a blocking dielectric, and a control gate which are sequentially stacked on the active region 305. The charge storage layer may be a floating gate comprising a semiconductor material. According to an embodiment, the charge storage layer may be a dielectric (e.g., nitride layer) having traps capable of storing charges. The blocking dielectric may include a high-k dielectric (e.g., hafnium oxide, or aluminum oxide) having a high dielectric constant compared with the tunnel dielectric. The blocking dielectric may be single-layered or multi-layered. The tunnel dielectric may be single-layered or multi-layered. The tunnel dielectric may include a thermal oxide. The string select line SSL may include a string select gate crossing the active region 305, and a first gate dielectric disposed between the string select gate and the active region 305. The ground select line GSL may include a ground select gate crossing the active region 305, and a second gate dielectric disposed between the ground select gate and the active region 305.

Each of the word lines WL, and the cell source/drain 310c positioned at both sides of each of the word lines WL may be included in a cell transistor. The string select line SSL and the common drain 310d and the cell source/drain 310c at both sides of the string select line SSL may be included in a string select transistor. The ground select line GSL, and the common source 310s and the cell source/drain 310c at both sides of the ground select line GSL may be included in a ground select transistor. A cell string may be formed in each of the active regions 305. The cell string may include a string select transistor, a ground select transistor, and a plurality of cell transistors connected in serial to each other. The string select transistor may be connected in serial to one end of the plurality of cell transistors, and the ground select transistor may be connected in serial to the other end of the plurality of cell transistors. The string select transistor, the cell transistors and the ground select transistor in the cell string according to the current embodiment may be arranged horizontally on the substrate 100.

A lower interlayer dielectric 103 may be disposed on the entire surface of the substrate 100 having the lines SSL, WL, GSL. A common source line CSL may be disposed in the lower interlayer dielectric 103 to extend in the second direction. The common source line CSL may be connected to the common sources 310s formed in the active regions 305.

Conductive pillars 105 may penetrate the lower interlayer dielectric 103 and be connected to the common drains 310d, respectively. The conductive pillars 105 may be arranged in a zigzag shape in the second direction.

The contact mold layer 110, the interconnections 150a, the contact parts 150c and the blocking dielectric patterns 115a described with reference to FIGS. 1A, 1B, 1C and 1D may be disposed on the lower interlayer dielectric 103. An upper interlayer dielectric 155 may be disposed on the interconnections 150a. At this time, air gaps 160 may be formed between the interconnections 150a. Each of the contact parts 150c may be connected to a top surface of each of the conductive pillars 105. Therefore, each of the interconnections 150a may be electrically connected to each of the common drains 310d. The interconnections 150a may correspond to bit lines of a semiconductor memory device. According to an embodiment, each of the interconnections 150a may be electrically connected to a drain of a string select transistor of a cell string arranged horizontally on the substrate 100.

The air gap 160 may be replaced by any one of the air gaps of FIGS. 2A to 2E. The blocking dielectric pattern 115a may be omitted, and the interconnection 150a may be disposed directly on the contact mold layer 110.

According to an embodiment, the interconnections 150a, the contact parts 150c and the conductive pillars 105 may be replaced by the interconnections 150a, the contact parts 150ca and the conductive pillars 105a of the foregoing second embodiment.

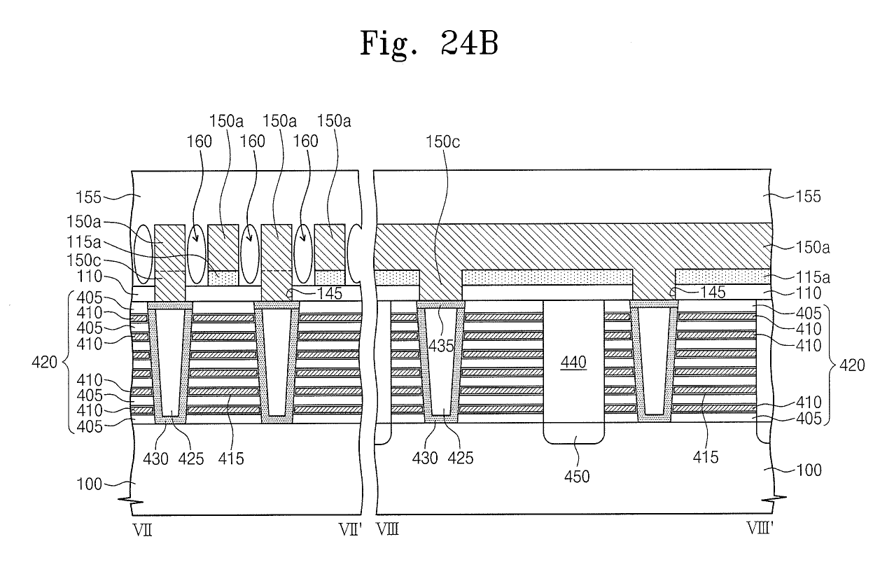

FIG. 24A is a plan view illustrating a semiconductor device according to an exemplary embodiment, and FIG. 24B is a cross-sectional view taken along lines VII-VII′ and VIII-VIII′ of FIG. 24A.

Referring to FIGS. 24A and 24B, a plurality of gate structures 420 may be disposed on a substrate 100. The gate structures 420 may be spaced apart from one another in a first direction. The gate structures 420 may extend in parallel in a second direction perpendicular to the first direction. The first and second directions may correspond to an x-axis direction and a y-axis direction of FIG. 24A, respectively. The substrate 100 may be doped with first conductive type dopants.

Each of the gate structures 420 may include dielectric patterns 405 and gate patterns 410 which are alternatingly and repeatedly stacked. A plurality of vertical type active patterns 430 may continuously penetrate the dielectric patterns 405 and the gate patterns 410 stacked. The vertical type active patterns 430 may contact the substrate 100. According to an embodiment, the vertical type active patterns 430 penetrating each of the gate structures 420 may be arranged in a zigzag shape in the second direction. The vertical type active pattern 430 may include a semiconductor material. The vertical type active pattern 430 may have an undoped state. Unlike this, the vertical type active pattern 430 may be in a state doped with the first conductive type dopants.

A data storage layer 415 may be disposed between a sidewall of the vertical active pattern 430 and the gate pattern 410. The storage layer 415 may include a tunnel dielectric, a charge storage layer, and a blocking dielectric. The tunnel dielectric may be adjacent to the vertical type active pattern 430, and the blocking dielectric may be adjacent to the gate pattern 410. The charge storage layer may be disposed between the tunnel dielectric and the blocking dielectric.

The vertical type active pattern 430 may have a hollow shell shape. In this case, the inside of the vertical type active pattern 430 may be filled by a filling dielectric pattern 425. A capping semiconductor pattern 435 may be disposed on the filling dielectric pattern 425. The capping semiconductor pattern 435 may contact the vertical type active pattern 430. The capping semiconductor pattern 435 may be at least doped with the second conductive type dopants to form a common drain. According to an embodiment, the vertical type active pattern 430 may have a pillar shape. In this case, the filling dielectric pattern 425 and the capping semiconductor pattern 435 may be omitted. When the vertical type active pattern 430 has a pillar shape, some portion of the vertical type active pattern 430 which is positioned at a higher level than the uppermost gate pattern among the gate patterns 410 may be doped with the second conductive type dopants and thus become the common drain. A common source region 450 may be disposed in the substrate 100 between the gate structures 420. The common source region 450 may be doped with the second conductive type dopants. A device isolation pattern 440 may fill a space between the gate structures 420.

Among the gate patterns 410 stacked in each of the gate structures, the lowermost gate pattern may be included in a ground select transistor, and the uppermost gate pattern may be included in a string select transistor. The gate patterns stacked between the lowermost gate pattern and the uppermost gate pattern may be included in cell transistors, respectively. The gate pattern included in the cell transistor may be defined as cell gate pattern. The cell transistor may be defined at a crossing region between each of the cell gate patterns and the vertical type active pattern 430. The cell transistor may have a nonvolatile characteristic. The ground select transistor, the cell transistors, and the string select transistor stacked may be connected in serial by the vertical type active pattern 430 to form a cell string. The transistors in the cell string may be stacked vertically on the top surface of the substrate 100.

The contact mold layer 110, the contact parts 150c, and the interconnections 150a described with reference to FIGS. 1A, 1B, 1C and 1D may be disposed on the gate structures 420 and the device isolation pattern 440. An upper interlayer dielectric 155 may be disposed on the interconnections 150a. At this time, air gaps 160 may be formed between the interconnections 150a. Each of the contact parts 150c connected to each of the interconnections 150a may be connected to the common drain. For example, each of the contact parts 150c may be connected to each of the capping semiconductor patterns 435. The interconnections 150a may be electrically connected to the vertical type active patterns 430 penetrating each of the gate structures 420, respectively. The air gap 160 may be replaced by any one of the air gaps of FIGS. 2A to 2E.

According to an embodiment, the contact parts 150c and the interconnections 150a may be replaced by the contact parts 150ca and the interconnections 150a of the foregoing second embodiment.

The semiconductor devices disclosed in the foregoing embodiments may be mounted in various types of packages. Examples of the packages of the semiconductor devices according to the exemplary embodiments may include at least one of package on package (PoP), ball grid arrays (BGAs), chip scale packages (CSPs), a plastic leaded chip carrier (PLCC), a plastic dual in-line package (PDIP), a die in waffle pack, a die in wafer form, a chip on board (COB), a ceramic dual in-line package (CERDIP), a plastic metric quad flat pack (MQFP), a thin quad flat pack (TQFP), a small outline package (SOP), a shrink small outline package (SSOP), a thin small outline package (TSOP), a thin quad flat package (TQFP), a system in package (SIP), a multi chip package (MCP), a wafer-level fabricated package (WFP), a wafer-level processed package (WSP), and so on.

The packages equipped with the semiconductor devices according to exemplary embodiments may further include semiconductor devices, e.g., controller and/or logic device, performing other functions.

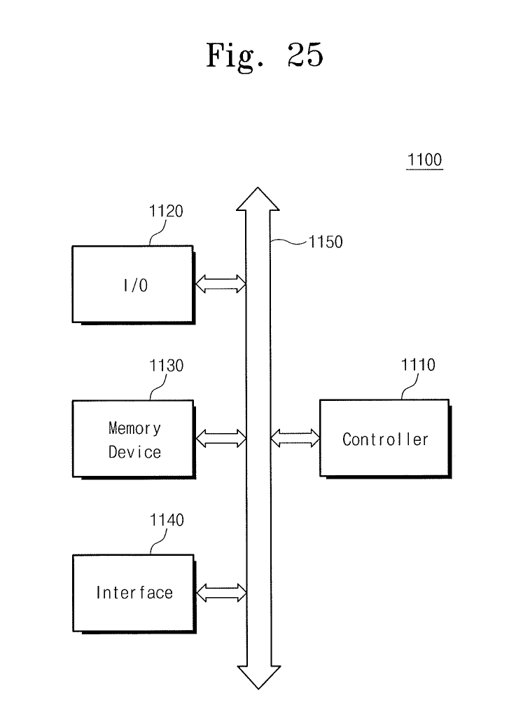

FIG. 25 is a block diagram illustrating an example of an electronic system including a semiconductor device based on an exemplary embodiment.

Referring to FIG. 25, an electronic system 1100 according to an exemplary embodiment o may include a controller 1110, an input/output device (I/O) 1120, a memory device 1130, an interface 1140, and a bus 1150. The controller 1110, the input/output device 1120, the memory device 1130 and/or the interface 1140 may be coupled to one another through the bus 1150. The bus 1150 corresponds to a path through which data is transmitted.

The controller 1110 includes at least one selected from the group consisting of a microprocessor, a digital signal processor, a microcontroller, and logic devices capable of performing similar functions to the above elements. In the case where the semiconductor devices disclosed in the foregoing first and second embodiments are implemented by logic devices, the controller 1110 may include any one of the semiconductor devices disclosed in the first and second embodiments. The input/output device 1120 may include a keypad, a keyboard, a display device and the like. The memory device 1130 may store data and/or commands. The memory device 1130 may include at least one among the semiconductor memory devices disclosed in the first to fourth embodiments. Also, the memory device 1130 may further include other types of semiconductor devices (e.g., DRAM device and/or SRAM device). The interface 1140 may serve to transmit/receive data to/from a communication network. The interface 1140 may include a wired and/or wireless interface. For example, the interface 1140 may include an antenna and/or a wired/wireless transceiver. Although not shown in the drawings, the electronic system 1100 may further include a high speed DRAM and/or SRAM as a working memory for enhancing operations of the controller 1110.

The electronic system 1100 may be applied to a personal digital assistant (PDA), a portable computer, a web tablet, a wireless phone, a mobile phone, a digital music player, a memory card, or all electronic products capable of transmitting/receiving information in a wireless environment.

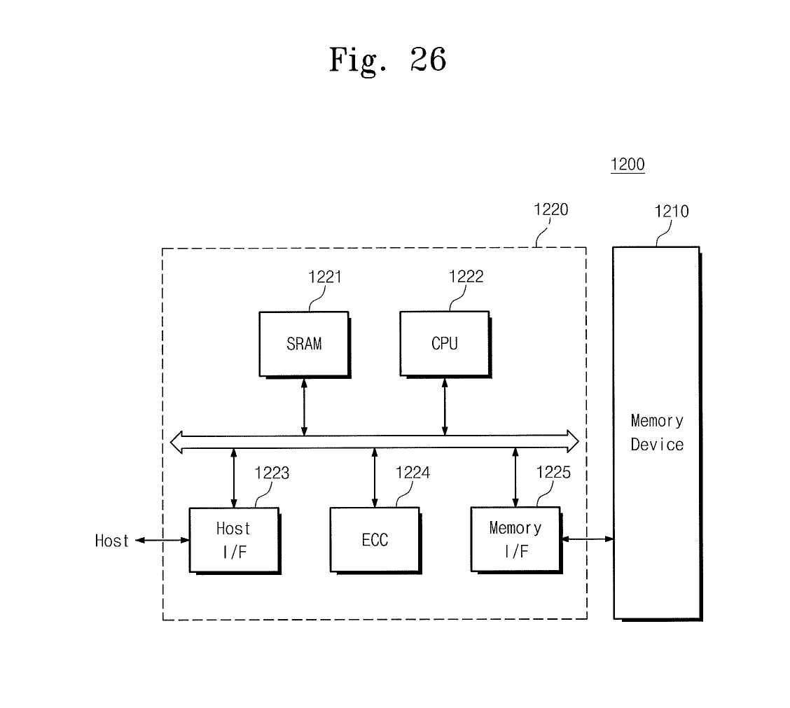

FIG. 26 is a block diagram illustrating an example of a memory card including a semiconductor device according to an exemplary embodiment.

Referring to FIG. 26, a memory card 1200, according to an exemplary embodiment, includes a memory device 1210. The memory device 1210 may include at least one among the semiconductor memory devices disclosed in the first to fourth embodiments. Also, the memory device 1210 may further include other types of semiconductor memory devices (e.g., DRAM device and/or SRAM device). The memory card 1200 may include a memory controller for controlling data exchange between a host and the memory device 1210.

The memory controller 1220 may include a processing unit (CPU) 1222 controlling an overall operation of the memory card 1200. Also, the memory controller 1220 may include an SRAM 1221 used as a working memory of the processing unit 1222. In addition, the memory controller 1220 may further include a host interface 1223 and a memory interface 1225. The host interface 1223 may be provided with a data exchange protocol between the memory card 1200 and the host. The memory interface 1225 may connect the memory controller 1220 and the memory device 1210. Furthermore, the memory controller 1220 may further include an error correction block (ECC) 1224. The ECC 1224 may detect and correct an error of data read from the memory device 1210. Although not shown in FIG. 10, the memory card 1200 may further include a ROM device storing code data for interfacing with the host. The memory card 1200 may be used as a portable data storage card. Alternatively, the memory card 1200 may be provided in the form of a solid state disk (SSD) that can substitute for a hard disk of a computer system.

According to the foregoing semiconductor devices, air gaps are formed between interconnections while an upper interlayer dielectric is disposed on the interconnections. Therefore, parasitic capacitance between the interconnections may be minimized. Also, the contact part may have the substantially same width as the interconnection. Therefore, a space between the interconnections may be decreased.

Although the exemplary embodiments have been described herein with reference to the accompanying drawings, it is to be understood that the present invention should not be limited to those precise embodiments and that various other changes and modifications may be affected therein by one of ordinary skill in the related art without departing from the scope or spirit of the invention. All such changes and modifications are intended to be included within the scope of the invention as defined by the appended claims.

1. A method of forming a nonvolatile memory device, the method comprising:
providing conductive pillars disposed in a first insulating layer and disposed on a semiconductor substrate;
providing an etch stop layer on the first insulating layer;
disposing a mold layer on the etch stop layer;
forming grooves in the mold layer, the grooves respectively extending over the conductive pillars in a first direction;
patterning the etch stop layer using the grooves to form holes respectively corresponding to the conductive pillars; and
filling a metal into the grooves and the holes, the metal in the holes contacting the conductive pillars.

2. The method of claim 1, wherein the metal filling the grooves forms bit lines extending in the first direction.

3. The method of claim 2, wherein the metal filling the holes forms metal contacts respectively contacting the conductive pillars.

4. The method of claim 3, wherein a width of a metal contact in a second direction is same as a width of a bit line in the second direction, the second direction being substantially perpendicular to the first direction.

5. The method of claim 2, further comprising forming a second insulating layer between the bit lines.

6. The method of claim 5, further comprising forming an air gap in the second insulating layer, the air gap extending in the first direction in between two immediately adjacent bit lines.

7. The method of claim 1, wherein the etch stop layer includes SiN.

8. The method of claim 1, further comprising providing a mask pattern on the mold layer to form the grooves.

9. A method of forming a nonvolatile memory device, the method comprising:
providing conductive pillars disposed in a first insulating layer and disposed on a semiconductor substrate;
providing an etch stop layer on the first insulating layer, the etch stop layer having holes;
disposing a mold layer on the etch stop layer;
forming grooves in the mold layer, the grooves respectively extending over the conductive pillars in a first direction;
patterning the mold layer in the holes using the grooves to form openings respectively corresponding to the conductive pillars; and
filling a metal into the grooves and the openings, the metal in the openings contacting the conductive pillars.

10. The method of claim 9, wherein the metal filling the grooves forms bit lines extending in the first direction.

11. The method of claim 10, wherein the metal filling the openings forms metal contacts respectively contacting the conductive pillars.

12. The method of claim 11, wherein a width of a metal contact in a second direction is same as a width of a bit line in the second direction, the second direction being substantially perpendicular to the first direction.

13. The method of claim 10, further comprising forming a second insulating layer between the bit lines.

14. The method of claim 13, further comprising forming an air gap in the second insulating layer, the air gap extending in the first direction in between two immediately adjacent bit lines.

15. The method of claim 9, wherein the etch stop layer includes SiN.

16. The method of claim 9, further comprising providing a mask pattern on the mold layer to form the grooves.

17-33. (canceled)
